(19) United States
(12) Patent Application Publication
(10) Pub. No.: US 2024/0419860 A1
(43) Pub. Date: Dec. 19, 2024

(54) Data-Driven Single-Ended Traveling Wave-Based Protection of Distribution Systems

(71) Applicant: Quanta Technology, LLC, Raleigh, NC (US)

(72) Inventors: Hadi Khani, Richmond Hill (CA); David G. Hart, Raleigh, NC (US); Solveig Ward, Cooperstown, PA (US); Damir Novosel, Cary, NC (US)

(21) Appl. No.: 18/337,143

(22) Filed: Jun. 19, 2023

(51) Int. Cl. G06F 30/20; G06F 30/3308

(52) U.S. Cl. CPC G06F 30/20; G06F 30/3308

(57) ABSTRACT

Relay configuration equipment helps configure a protective relay for single-ended traveling wave-based protection of an electric power system. The relay configuration equipment obtains relay settings for a protective relay specifying characteristics of traveling waves attributable to fault events that are to trip the relay. The relay configuration equipment performs event simulations, including fault events and non-fault events, in the electric power system under different configurations. The relay configuration equipment then iteratively adapts settings for the relay by, in each iteration, identifying characteristics of traveling waves attributed to the simulated event, applying settings to the characteristics to determine an observed local response of the relay to the event, and generating data comparing the observed local response with an expected local response. The relay configuration equipment revises settings for the relay based on this data, to realize a data-driven approach to protective relay configuration.

### TECHNICAL FIELD

The present application relates generally to an electric power system, and relates more particularly to traveling wave-based protection of an electric power system.

### BACKGROUND

In an electric power system, a fault event is any abnormal condition of the system that causes currents and/or voltages in the system to deviate from their nominal values and/or results in energy being dissipated in a manner other than serving the intended load. In a ground fault event, for example, current flows into the Earth, disrupting the nominal currents and voltages of the system. A fault event may be caused by any number of sources, such as the failure of electrical equipment in the system, human errors, and/or environmental phenomena. Regardless, the deviation in the currents and/or voltages in the system interrupts the normal electrical flows, risks equipment damage, and/or poses safety hazards to humans. A fault event may for example ignite a forest fire.

A fault protection system detects the occurrence of a fault event so that actions can be taken to protect against the fault event. The actions may include remedial actions to restore the electric power system to a non-fault state and/or include safety measures to guard against possible harm from the fault event. The fault protection system may for instance trip a protective relay upon occurrence of a fault event, in order to isolate the fault event and its impact.

In order to protect against some types of fault events, the fault protection system must detect the fault event and disconnect faulted circuits very quickly, with high speed, e.g., within a quarter of a cycle. Such high-speed tripping may for example be effective for preventing forest fires ignited by power lines. Traditional, impedance-based protection may be slow or ineffective in these and other cases, e.g., with delays due to filtering taking up to one full cycle.

One approach to high-speed tripping exploits so-called traveling waves (TWs). A fault event produces traveling waves, in the form of transient non-power frequency signals, that propagate across the electric power system as they reflect and/or refract from different nodes in the system. Traveling wave-based protection detects fault events by observing peaks of traveling waves at relay measuring point(s). Traveling waves travel at close to the speed of light so as to provide the first information about a fault event. Traveling waves can therefore be used to very quickly detect the occurrence, type, location, and/or inception angle of fault events, e.g., within a few milliseconds. Problematically, though, traveling waves can also occur from non-fault events, such as load or capacitor bank switching. For reliability, then, traveling wave-based protection must differentiate between traveling waves attributable to fault events and traveling waves attributable to non-fault events.

Double-ended traveling wave-based approaches are heretofore considered more reliable than single-ended traveling wave-based approaches. In single-ended approaches, a protective relay makes tripping decisions based only on traveling wave measurements performed locally at the protective relay. By contrast, in double-ended approaches, a protective relay makes tripping decisions based on both traveling wave measurements performed locally and traveling wave measurements performed remotely at another protective relay. Double-ended approaches therefore require strict time synchronization between protective relays, as well as a communication channel between protective relays, and so are more expensive and more complicated than single-ended approaches. Yet challenges exist in how to configure protective relays for realizing single-ended traveling wave-based protection that is reliable, especially in complicated electric power systems.

### SUMMARY

Embodiments herein exploit simulations of events in an electric power system to tailor a protective relay's settings for single-ended traveling wave-based protection. Some embodiments simulate both fault events and non-fault events in order for the protective relay's settings to reliably differentiate between characteristics of traveling waves attributable to fault events and characteristics of traveling waves attributable to non-fault events. Moreover, some embodiments simulate such events under different configurations of the electric power system, so that the protective relay's settings prove robust to changing power system circumstances, e.g., different load levels and/or different distributed energy resource (DER) conditions. With data from the simulations driving the protective relay's settings, some embodiments herein are applicable for realizing single-ended traveling wave-based protection even in complex electric power systems. The single-ended nature of the protection embodiments meanwhile avoids synchronization and communication channel requirements of double-ended protection, thereby reducing the cost and complexity of protection.

More particularly, embodiments herein include a method for single-ended traveling wave-based protection of an electric power system. The method includes obtaining relay settings for a protective relay specifying characteristics of traveling waves attributable to fault events that are to trip the protective relay. The method also includes performing simulations of events in the electric power system under different power system configurations, with the events including fault events and non-fault events, to obtain, for each of the simulations, an output file indicating characteristics of traveling waves attributed to the event simulated. The method also includes iteratively adapting the relay settings for the protective relay over one or more iterations. In some embodiments, adapting the relay settings in each iteration comprises, for each of the simulations, parsing the output file for the simulation to identify characteristics of traveling waves attributed to the event simulated, applying the relay settings to the identified characteristics to determine an observed local response of the protective relay to the simulated event, and generating comparison data that compares the observed local response of the protective relay to the simulated event with an expected local response of the protected relay to the simulated event. In some embodiments, adapting the relay settings in each iteration comprises revising the relay settings for the protective relay based on the comparison data generated for the simulations.

In some embodiments, a simulation settings file specifies, for each of the simulations, the event to be simulated as well as the power system configuration under which the simulation is to be performed. In some embodiments, performing the simulations comprises, for each of the simulations, obtaining settings specific to the simulation by parsing the simulation settings file. In some embodiments, performing the simulations comprises, for each of the simulations, performing the simulation with the obtained settings. In some embodiments, performing the simulations comprises, for each of the simulations, determining, from the obtained settings, a simulation identifier that identifies the simulation. In some embodiments, performing the simulations comprises, for each of the simulations, labeling the output file for the simulation with the simulation identifier. In some embodiments, for each of the simulations, adapting the relay settings in each iteration further comprises determining the expected local response of the protective relay to the simulated event from how the output file for the simulation is labeled. In some embodiments, labeling the output file for the simulation with the simulation identifier comprises naming the output file for the simulation with the simulation identifier. In some embodiments, the simulation settings file includes an array for each simulation. In some embodiments, the array for each simulation includes a combination of settings identifiers that comprises two or more event setting identifiers for different types of event settings and/or two or more system configuration setting identifiers for different types of system configuration settings. In some embodiments, each event settings identifier of a given type identifies one out of multiple candidate preconfigured event settings of the given type, and each system configuration setting identifiers identifies one out of multiple candidate preconfigured system configuration settings of the given type. In some embodiments, the different types of event settings include at least a location setting specifying a location of an event and an event type setting specifying a type of an event, and the different types of system configuration settings include at least a load setting specifying a loading on the electric power system and a distributed energy resource setting specifying a presence and/or type of distributed energy resources in the electric power system. In some embodiments, determining the simulation identifier for each simulation comprises generating the simulation identifier by concatenating the settings identifiers included in the array for the simulation.

In some embodiments, characteristics of traveling waves include a peak value and/or polarity of a current wave. In other embodiments, characteristics of traveling waves alternatively or additionally include a peak value and/or polarity of a voltage wave.

In some embodiments, the simulations are electromagnetic transients program simulations.

In some embodiments, adapting the relay settings comprises adapting the relay settings as needed to maximize a number of simulated fault events that the protective relay trips in response to, while preventing the protective relay from tripping in response to any simulated non-fault event. In some embodiments, according to the relay settings as adapted, the protective relay does not trip in response to a subset of fault events simulated, and the method further comprises determining, from the simulations, impedance-based element settings for a backup impedance-based element specifying an impedance attributable to fault events in the subset that are to trip the backup impedance-based element. In some embodiments, determining the impedance-based element settings comprises estimating, from transmission line output files output from the simulations, line impedances at locations of respective fault events simulated. In some embodiments, determining the impedance-based element settings comprises calculating the impedance-based element settings from the estimated line impedances. In some embodiments, determining the impedance-based element settings further comprises estimating, using the output files output from the simulations, fault impedances associated with the respective events simulated. In some embodiments, determining the impedance-based element settings further comprises verifying the impedance-based element settings as a function of the estimated fault impedances.

In some embodiments, the method further comprises configuring the protective relay with the relay settings as adapted.

Other embodiments herein include a non-transitory computer-readable medium on which is stored instructions. In some embodiments, the instructions, when executed by a processor, cause the processor to obtain relay settings for a protective relay specifying characteristics of traveling waves attributable to fault events that are to trip the protective relay. In some embodiments, the instructions, when executed by a processor, cause the processor to perform simulations of events in the electric power system under different power system configurations, with the events including fault events and non-fault events, to obtain, for each of the simulations, an output file indicating characteristics of traveling waves attributed to the event simulated. In some embodiments, the instructions, when executed by a processor, cause the processor to iteratively adapt the relay settings for the protective relay over one or more iterations. In some embodiments, adapting the relay settings in each iteration comprises, for each of the simulations, parsing the output file for the simulation to identify characteristics of traveling waves attributed to the event simulated, applying the relay settings to the identified characteristics to determine an observed local response of the protective relay to the simulated event, and generating comparison data that compares the observed local response of the protective relay to the simulated event with an expected local response of the protected relay to the simulated event. In some embodiments, adapting the relay settings in each iteration comprises revising the relay settings for the protective relay based on the comparison data generated for the simulations.

In some embodiments, a simulation settings file specifies, for each of the simulations, the event to be simulated as well as the power system configuration under which the simulation is to be performed. In some embodiments, the instructions, when executed by the processor, cause the processor to perform the simulations by, for each of the simulations, obtaining settings specific to the simulation by parsing the simulation settings file. In some embodiments, the instructions, when executed by the processor, cause the processor to perform the simulations by, for each of the simulations, performing the simulation with the obtained settings. In some embodiments, the instructions, when executed by the processor, cause the processor to perform the simulations by, for each of the simulations, determining, from the obtained settings, a simulation identifier that identifies the simulation. In some embodiments, the instructions, when executed by the processor, cause the processor to perform the simulations by, for each of the simulations, labeling the output file for the simulation with the simulation identifier. In some embodiments, the instructions, when executed by the processor, cause the processor to, for each of the simulations, parse the output file for the simulation to identify characteristics of traveling waves attributed to the event simulated by identifying the characteristics of traveling waves attributed to the event simulated from how the output file is labeled. In some embodiments, the instructions, when executed by the processor, cause the processor to label the output file for the simulation with the simulation identifier by naming the output file for the simulation with the simulation identifier. In some embodiments, the simulation settings file includes an array for each simulation. In some embodiments, the array for each simulation includes a combination of settings identifiers that comprises two or more event setting identifiers for different types of event settings and/or two or more system configuration setting identifiers for different types of system configuration settings. In some embodiments, each event settings identifier of a given type identifies one out of multiple candidate preconfigured event settings of the given type, and each system configuration setting identifiers identifies one out of multiple candidate preconfigured system configuration settings of the given type. In some embodiments, the different types of event settings include at least a location setting specifying a location of an event and an event type setting specifying a type of an event, and the different types of system configuration settings include at least a load setting specifying a loading on the electric power system and a distributed energy resource setting specifying a presence and/or type of distributed energy resources in the electric power system. In some embodiments, the instructions, when executed by the processor, cause the processor to generate the simulation identifier by concatenating the settings identifiers included in the array for the simulation.

In some embodiments, characteristics of traveling waves include a peak value and/or polarity of a current wave. In other embodiments, characteristics of traveling waves alternatively or additionally include a peak value and/or polarity of a voltage wave.

In some embodiments, the simulations are electromagnetic transients program simulations.

In some embodiments, the instructions, when executed by the processor, cause the processor to adapt the relay settings as needed to maximize a number of simulated fault events that the protective relay trips in response to, while preventing the protective relay from tripping in response to any simulated non-fault event. In some embodiments, according to the relay settings as adapted, the protective relay does not trip in response to a subset of fault events simulated, and the instructions, when executed by the processor, cause the processor to determine, from the simulations, impedance-based element settings for a backup impedance-based element specifying an impedance attributable to fault events in the subset that are to trip the backup impedance-based element. In some embodiments, the instructions, when executed by the processor, cause the processor to determine the impedance-based element settings by estimating, from transmission line output files output from the simulations, line impedances at locations of respective fault events simulated. In some embodiments, the instructions, when executed by the processor, cause the processor to determine the impedance-based element settings by calculating the impedance-based element settings from the estimated line impedances. In some embodiments, the instructions, when executed by the processor, cause the processor to determine the impedance-based element settings by estimating, using the output files output from the simulations, fault impedances associated with the respective events simulated. In some embodiments, the instructions, when executed by the processor, cause the processor to determine the impedance-based element settings by verifying the impedance-based element settings as a function of the estimated fault impedances.

In some embodiments, the instructions, when executed by the processor, cause the processor to configure the protective relay with the relay settings as adapted.

Other embodiments herein include equipment for single-ended traveling wave-based protection of an electric power system. The equipment comprises processing circuitry. The processing circuitry is configured to obtain relay settings for a protective relay specifying characteristics of traveling waves attributable to fault events that are to trip the protective relay. The processing circuitry is also configured to perform simulations of events in the electric power system under different power system configurations, with the events including fault events and non-fault events, to obtain, for each of the simulations, an output file indicating characteristics of traveling waves attributed to the event simulated. The processing circuitry is also configured to iteratively adapt the relay settings for the protective relay over one or more iterations. In some embodiments, adapting the relay settings in each iteration comprises, for each of the simulations, parsing the output file for the simulation to identify characteristics of traveling waves attributed to the event simulated, applying the relay settings to the identified characteristics to determine an observed local response of the protective relay to the simulated event, and generating comparison data that compares the observed local response of the protective relay to the simulated event with an expected local response of the protected relay to the simulated event. In some embodiments, adapting the relay settings in each iteration comprises, for each of the simulations, revising the relay settings for the protective relay based on the comparison data generated for the simulations.

Of course, the present disclosure is not limited to the above features and advantages. Indeed, those skilled in the art will recognize additional features and advantages upon reading the following detailed description, and upon viewing the accompanying drawings.

### BRIEF DESCRIPTION OF THE DRAWINGS

FIG. 1 is a block diagram of an electric power system with a protective relay configured for traveling wave-based protection according to some embodiments.

FIG. 2 is a block diagram of equipment configured for simulation-based configuration of a protective relay for traveling wave-based protection of an electric power system according to some embodiments.

FIG. 3 is a block diagram of additional details of the equipment in FIG. 2 according to some embodiments.

FIG. 4 is a block diagram of additional details of the simulator in FIG. 2 according to some embodiments.

FIG. 5 is a logic flow diagram of processing for performing the simulations according to some embodiments.

FIG. 6 is a block diagram of one implementation of some embodiments herein, where the simulations are PSCAD simulations and the output files are PSCAD .OUT files.

FIG. 7 shows sample traveling wave reflection plots (voltage and current signals) for a three-phase fault (TPH).

FIG. 8 shows plots for a bolted single-line-to-ground (SLG) fault.

FIG. 9 shows plots for a resistive SLG fault.

FIG. 10 shows plots for capacitor bank switching.

FIG. 11 shows plots for load switching.

FIG. 12 is a block diagram of an electric power system with a protective relay configured for traveling wave-based protection and impedance-based protection according to some embodiments.

FIG. 13 is a block diagram of equipment configured for simulation-based configuration of a protective relay for traveling wave-based protection of an electric power system and a backup impedance-based element for impedance-based protection, according to some embodiments.

FIG. 14 is a block diagram of configuration of a backup impedance-based element for impedance-based protection according to some embodiments.

FIG. 15 is a block diagram of configuration of a protective relay for traveling wave-based protection of an electric power system and a backup impedance-based element for impedance-based protection, according to some embodiments.

FIG. 16 shows a test system and the location of simulated faults in an example.

FIG. 17A is a plot of relevant faults that occur, as seen by Recloser 1 when Regulator 2 is in-circuit.

FIG. 17B is a block diagram of a reference of all fault locations in FIG. 17A.

FIG. 18 is a zoomed-out version of FIG. 17A showing out-of-zone faults and switching events for Reclosure 1 according to some embodiments.

FIG. 19A is a plot of relevant faults that occur, as seen by Reclosure 2 when Regulator 2 is in-circuit.

FIG. 19B is a block diagram of a reference of all fault locations in FIG. 19A.

FIG. 20 is a zoomed-out version of FIG. 19A showing out-of-zone faults and switching events for Reclosure 2 according to some embodiments.

FIG. 21 is a logic flow diagram of a method performed by relay configuration equipment according to some embodiments.

FIG. 22 is a block diagram of relay configuration equipment according to some embodiments.

### DETAILED DESCRIPTION

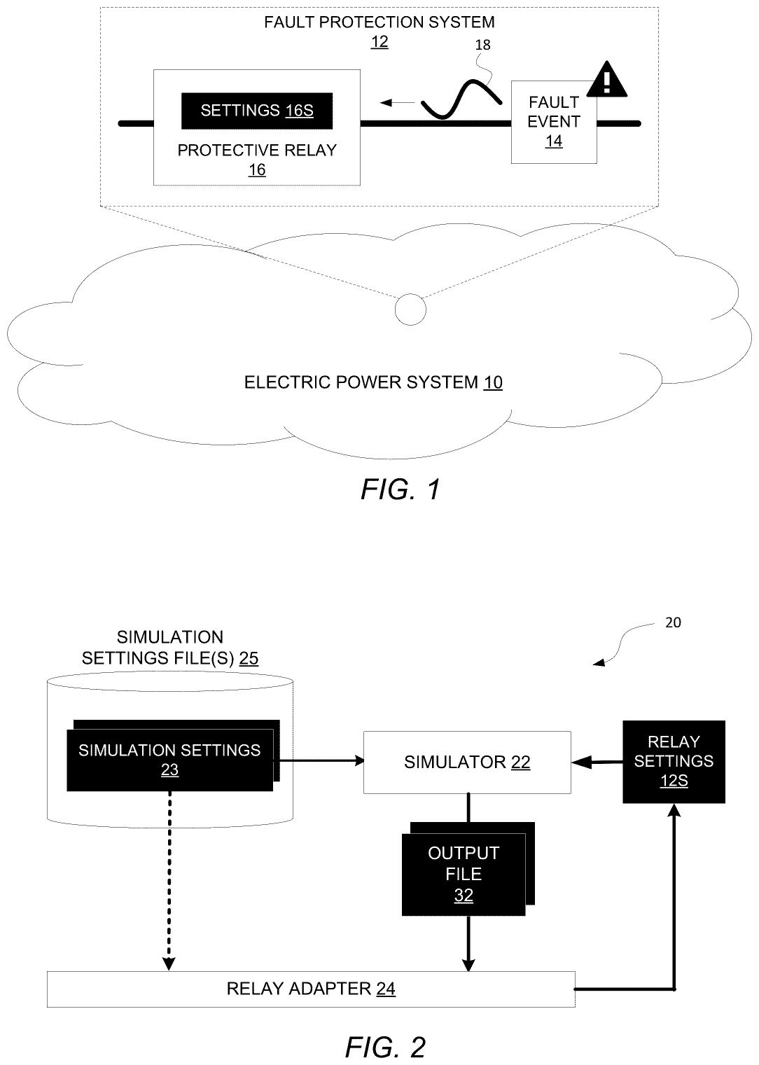

FIG. 1 shows an electric power system 10 according to some embodiments. The electric power system 10 may for example be a system configured to generate, distribute, and/or transmit electric power, e.g., as provided by an electric utility. However, an abnormal condition of the electric power system 10, known as a fault event 14, can cause currents and/or voltages in the electric power system 10 to deviate from their nominal values and/or result in energy being dissipated in a manner other than serving the intended load. A fault event 14 may be caused by any number of sources, such as the failure of electrical equipment in the electrical power system 10, human errors, and/or environmental phenomena. Regardless, the deviation in the currents and/or voltages in the electric power system 10 interrupts the normal electrical flows, risks equipment damage, and/or poses safety hazards to humans.

A fault protection system 12 in FIG. 1 detects the occurrence of a fault event 14, so that actions can be taken to protect against the fault event 14. The actions may include remedial actions to restore the electric power system 10 to a non-fault state and/or include safety measures to guard against possible harm from the fault event 14. The fault protection system 12 as shown in this regard includes one or more protective relays, one of which is shown as protective relay 16.

The protective relay 16 in FIG. 1 is configured to detect a fault event 14 by detecting a traveling wave 18 that propagates across the electric power system 10 upon the occurrence of a fault event 14. The traveling wave 18 may for instance be a current wave or a voltage wave. Settings 16S of the protective relay 16 in this regard specify characteristics of traveling waves 18 that are attributable to fault events 14, e.g., where such traveling waves may be characterized by their peak values and/or polarities. The settings 16S may for example specify that traveling waves 18 with a peak value above a threshold are attributable to fault events 14, whereas traveling waves 18 with a peak value below the threshold are attributable to non-fault events. Regardless, when the protective relay 16 detects a traveling wave 18 attributable to a fault event 14 according to its settings 16S, the protective relay 16 trips, e.g., to isolate or otherwise address the fault event 14. By basing its trip decision exclusively on traveling wave measurements performed locally at the protective relay 16, the protective relay 16 implements traveling wave-based protection that is single-ended. The protective relay 16 thereby requires neither strict time synchronization with any other protective relay nor a communication channel with another protective relay.

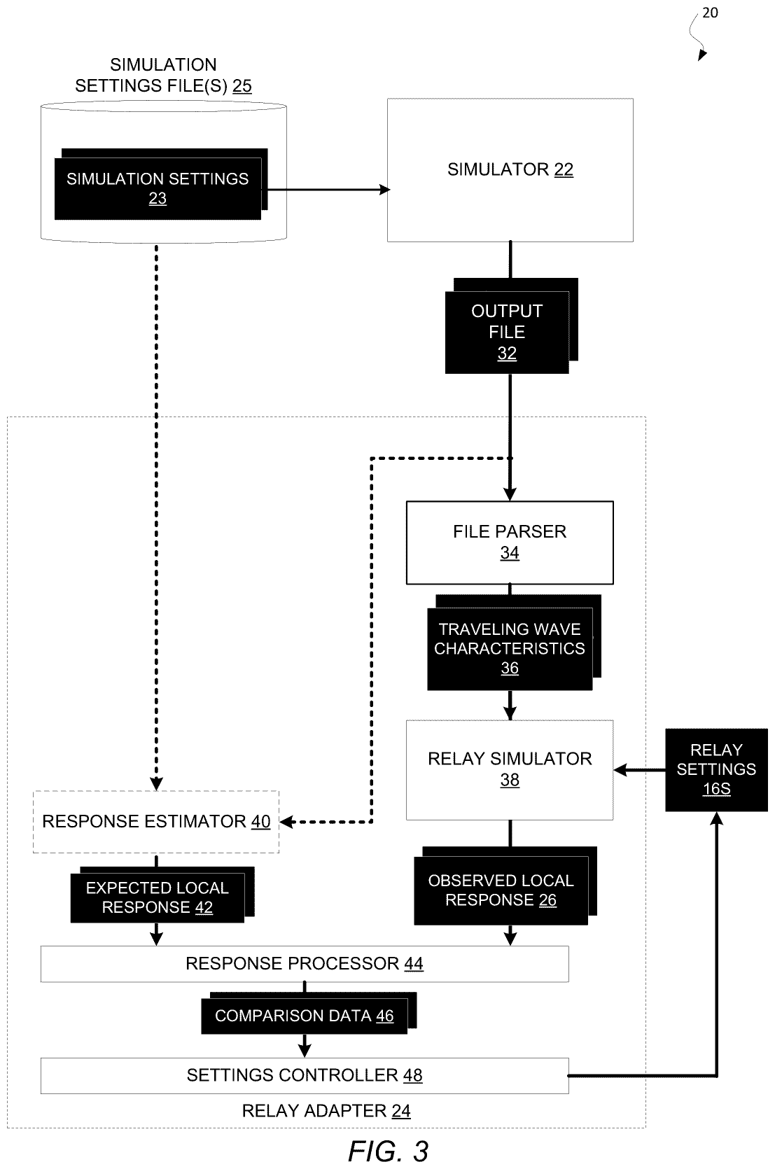

FIG. 2 shows relay configuration equipment 20 herein that exploits simulations of events in the electric power system 10 in order to tailor the protective relay's settings 16S for single-ended traveling wave-based protection. With data from the simulations driving the protective relay's settings 16S, the relay configuration equipment 20 facilitates configuring the protective relay 16 for single-ended traveling wave-based protection even in complex electric power systems. The single-ended nature of the protection embodiments meanwhile avoids synchronization and communication channel requirements of double-ended protection, thereby reducing the cost and complexity of protection.

As more specifically shown in FIG. 2, the relay configuration equipment 20 includes a simulator 22 and a relay adapter 24. The simulator 22 performs simulations of events in the electric power system 10, e.g., according to simulation settings 23 in a simulation settings file 25 The simulated events include both fault events and non-fault events. Moreover, the events may be simulated under different configurations of the electric power system 10, e.g., different load levels and/or different distributed energy resource (DER) conditions.

For each of the simulations, the simulator 22 obtains an output file 32. Each output file 32 indicates characteristics of traveling waves attributed to the event simulated. In embodiments where the simulations are electromagnetic transients program (ETM) simulations, e.g., Power System Computer Aided Design (PSCAD) simulations, the output files 32 may for instance be .OUT files (formatted text) or .PSOUT files (binary).

The relay adapter 24 then adapts the relay settings 16S based on the output file(s) 32 from the simulations. The relay adapter 24 in particular adapts the relay settings 16S as needed to configure the protective relay 16 to respond to fault events by tripping and to respond to non-fault events by not tripping. In one such embodiment, the relay adapter 24 adapts the relay settings 16S as needed to maximize the number of simulated fault events that the protective relay 16 trips in response to, while preventing the protective relay 16 from tripping in response to any simulated non-fault event, e.g., so as to prioritize security over dependability. In any event, the relay configuration equipment 20 may use observations from the simulations to effectively train the relay settings 16S so that the protective relay's responses reliably distinguish fault events from non-fault events.

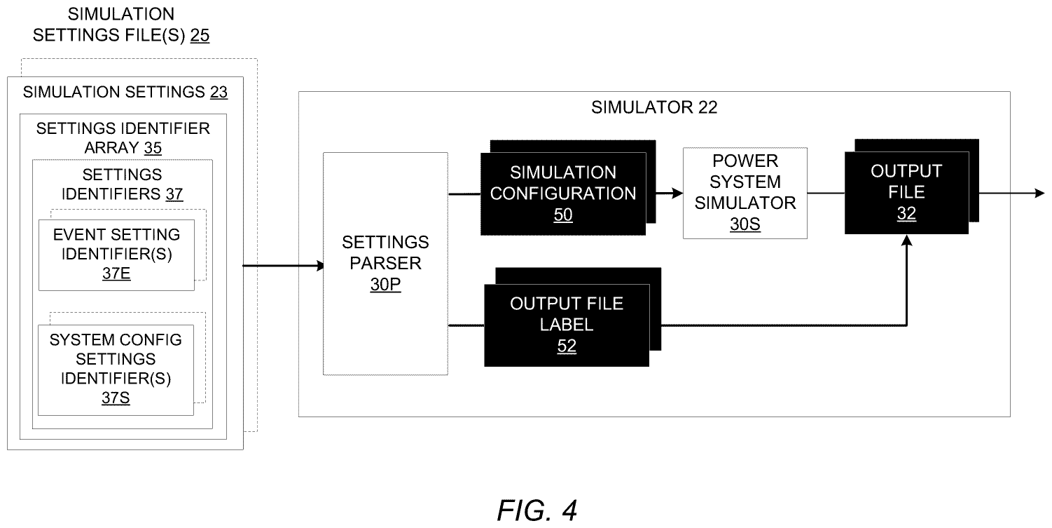

FIG. 3 illustrates still additional details of the relay configuration equipment 20 according to some embodiments. As shown, the relay adapter 24 includes a file parser 34. The file parser 34 parses the output file 32 that is output from each simulation, e.g., to extract voltage, current, and other traveling wave data. The file parser 34 does so to identify characteristics 36 of traveling waves 18 attributed to the event simulated in each simulation. With both fault events and non-fault events simulated, the resulting traveling wave characteristics 36 represent how the traveling waves 18 differ for fault events and non-fault events.

The relay adapter 24 also includes a relay simulator 38. The relay simulator 38 effectively simulates how the protective relay 16 would locally respond to traveling waves with the identified characteristics 36, if the protective relay 16 were configured with certain relay settings 16S. The relay simulator 38 does so by applying the relay settings 16S to the identified characteristics 36 of traveling waves resulting from each simulation and observing the local responses of the protective relay 16. For each simulation, then, the relay simulator 38 determines the observed local response 26 of the protective relay 16 to the event simulated in that simulation.

The relay adapter 24 is configured to determine the corresponding local responses 42 expected for the simulations. In one embodiment, for example, the simulation settings 23 explicitly indicate the expected local responses 42, in which case the relay adapter 24 simply reads the expected local responses 42 for the corresponding simulations from the simulation settings 23. In another embodiment, though, the relay adapter 24 includes a response estimator 40 that interprets or otherwise derives the expected local responses 42 from the simulation settings 23 and/or the output files 32. For example, the response estimator 40 may deduce the expected local response from any given simulation from the type of event simulated in the simulation or map an identifier associated with a simulation to an expected local response.

For each simulation, a response processor 44 of the relay adapter 24 compares the observed local response 26 of the protective relay 16 to the simulated event with the expected local response 42 of the protective relay 16 to the simulated event. This comparison produces comparison data 46. The comparison data 46 may for example take the form of a results matrix, graph(s), plot(s), chart(s), MATrix LABoratory (MATLAB) file(s), or any other data that compares the observed local responses 26 with the corresponding expected local responses 42. The comparison data 46 in some embodiments compares the observed local responses 26 with the corresponding expected local responses 42 at a low level, with fine granularity, e.g., by indicating which observed local responses 26 match the corresponding expected local responses 26 and which observed local responses 26 do not match the corresponding expected local responses 26. In other embodiments, the comparison data 46 includes statistical data summarizing the comparison at a high level, with coarse granularity, e.g., by indicating how many observed local responses 26 match the corresponding expected local responses 42 and/or how many observed local responses 42 do not match the corresponding expected local responses 26.

No matter the particular form of the comparison data 46, a settings controller 48 controls the relay settings 16S based on that comparison data 46. If the observed local responses 26 do not match the expected local responses 42 to the required extent, for example, the settings controller 48 may revise the relay settings 16S for the protective relay 16, e.g., to better align the observed local responses 26 with the expected local responses 42. In these and other embodiments, the settings controller 48 may adapt the relay settings 16S in this way iteratively, over one or more iterations. In one such embodiment, then, the settings controller 48 refines the relay settings 16S iteration by iteration, with each iteration targeting improvement in the match between observed local responses 26 and expected local responses 42. Generally, then, the settings controller 48 may iteratively adapt the relay settings 16S until the local responses 26 observed from the simulations align to a desired extent to the local responses that are expected.

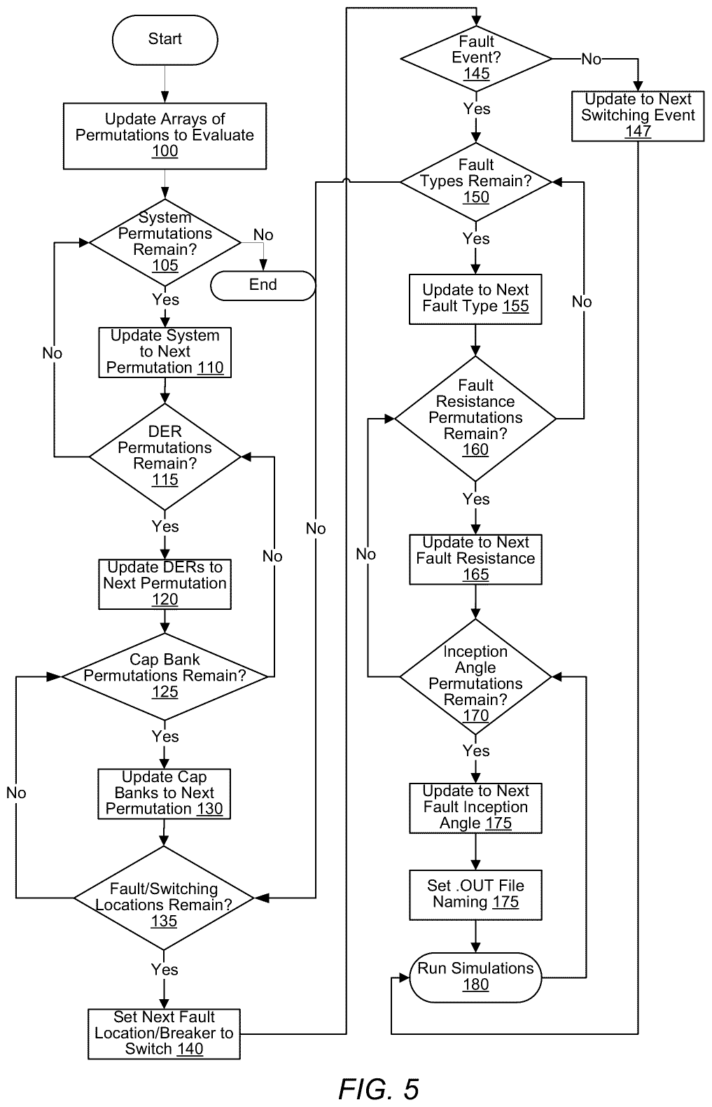

FIG. 4 illustrates additional details of the simulator 22 according to some embodiments. In these embodiments, the simulation settings file 25 specifies, for each of the simulations, the event to be simulated as well as a power system configuration under which the simulation is to be performed. In one embodiment, the simulation settings file 25 explicitly specifies the event to be simulated by specifying one or more parameters that define or govern the event, and/or explicitly specifies the power system configuration by specifying one or more parameters that define or govern the power system configuration. In other embodiments, though, the simulation settings file 25 exploits identifiers to indirectly specify the event and/or the power system configuration.

As shown in FIG. 4, for example, the simulation settings file 25 includes an array 35 for each simulation, shown as settings identifier array 35. The array 35 for each simulation includes a combination of settings identifiers 37. The combination of settings identifiers 37 includes two or more event setting identifiers 37E for different types of event settings. The different types of event settings may for instance include a location setting specifying a location of an event in the electric power system 10 and an event type setting specifying a type of an event. Alternatively or additionally, the event settings may specify a fault event in terms of its location, type, inception angle, resistance, etc., and/or specify a non-fault event in terms capacitor bank switching parameters or load switching parameters. A combination of event settings identifiers 37E may thereby define an event in a number of dimensions. For example, event 1 may be defined as a bolted single line to ground fault at reclosure 1, event 2 may be defined as a three-phase fault at reclosure 2, event 3 may be defined as a capacitor bank switching event at a certain location, event 4 may be defined as a load switching event at another location, etc. In these and other embodiments, then, each event settings identifier 37E of a given type may identify one out of multiple candidate preconfigured event settings of the given type.

Similarly, the array 35 for each simulation as shown also includes two or more system configuration setting identifiers 37S for different types of system configuration settings. The different types of system configuration settings may for example include a load setting specifying a loading on the electric power system 10 and a distributed energy resource (DER) setting specifying a presence and/or type of DERs in the electric power system 10. Alternatively or additionally, the system configuration settings may specify a primary system configuration, specify any capacitor banks, and/or specify any load banks. A combination of system configuration settings identifiers 37S may thereby define a power system configuration in a number of dimensions. In these and other embodiments, then, each system configuration settings identifier 37S of a given type may identify one out of multiple candidate preconfigured system configuration settings of the given type.

The simulations may thereby be configured via combinations of settings identifiers 37. The simulations in this case may amount to different permutations of events and system configurations.

The simulator 22 also includes a settings parser 30P that parses the simulation settings file(s) to translate the settings identifiers 37 into configuration(s) 50 specific to the simulations to be performed. The settings parser 30P for example maps combinations of settings identifiers 37 into corresponding combinations of parameters that govern the simulations, where each combination of parameters amounts to a configuration 50 specific to a simulation to be performed. A power system simulator 30S receives these configurations 50 as input, performs the simulations as configured, and produces output files 32 representing results of the simulations.

The settings parser 30P in FIG. 4 also obtains labels 52 for respective output files 32 from the simulation settings 23. In particular, for each simulation, the settings parser 30P determines, from the settings 23 for that simulation, a simulation identifier that identifies the simulation. The settings parser 30P forms or otherwise determines an output file label 52 from that simulation identifier. The settings parser 30P may for example generate the simulation identifier for a simulation by concatenating the settings identifiers 37 included in the array 35 for the simulation. Power system simulator 30 labels the output file 32 with the corresponding label 52 for each simulation. The simulator 22 may for instance embed the label for an output file 32 into that output file 32. Or, the simulator 22 may name the output file 32 for a simulation with the label 52.

Consider some embodiments herein where the simulator 22 names the output files 32 according to a certain file naming convention. In one such embodiment, the settings parser 30P determines the simulation identifier for each simulation as a unique identifier assigned to each permutation of settings. The label 52 for a simulation may for example be the concatenation of the setting identifiers 37, separated by underscores or some other delimiter.

For simulations of a fault event, for instance, the label 52 for the simulation may be defined as:
[Primary System Config.]_[DERs]_[Cap
Banks]_[Location]_[Type]_[Resistance]_[Inception Angle]
   with the corresponding output file 32 being named as:
[Primary System Config.]_[DERs]_[Cap
Banks]_[Location]_[Type]_[Resistance]_[Inception Angle].OUT
   As an example, the output file for a fault simulation may be name as:
HLoad_Wndln_Capln_Flt4_TPH_R0_A9
   From the file naming convention, the name of the output file 32 indicates the simulation parameters as:
Primary System Configuration: Highly Loaded
DERs: Wind Generators in Circuit
Capacitor Banks: Capacitor Banks in Circuit
Fault Location: Location Four
Fault Type: Three-phase-to-ground
Fault Resistance: 0 Ohm
Fault Inception Angle: 90°

As another example, for simulations of capacitor or load switching events, the label 52 for the simulation may be defined as:
[Primary System Config]_[DERs]_[Cap Banks]_[Cap or Load to Switch] with the corresponding output file 32 being named as:
[Primary System Config]_[DERs]_[Cap Banks]_[Cap or Load to Switch].OUT

In these and other embodiments, then, the name of each output file 32 provides information about the corresponding simulation, including the expected local response 42. Indeed, if the name of an output file 32 follows the file naming convention for a fault event, the expected local response 42 is for the protective relay 16 to trip, whereas if the name of an output file 32 follows the file naming convention for a non-fault event, the expected local response 42 is for the protective relay 16 to refrain from tripping. Accordingly, in some embodiments, the relay adapter 24 determines the expected local response 42 of the protective relay 16 to a simulated event from how the output file 32 for a simulation is labeled, e.g., named.

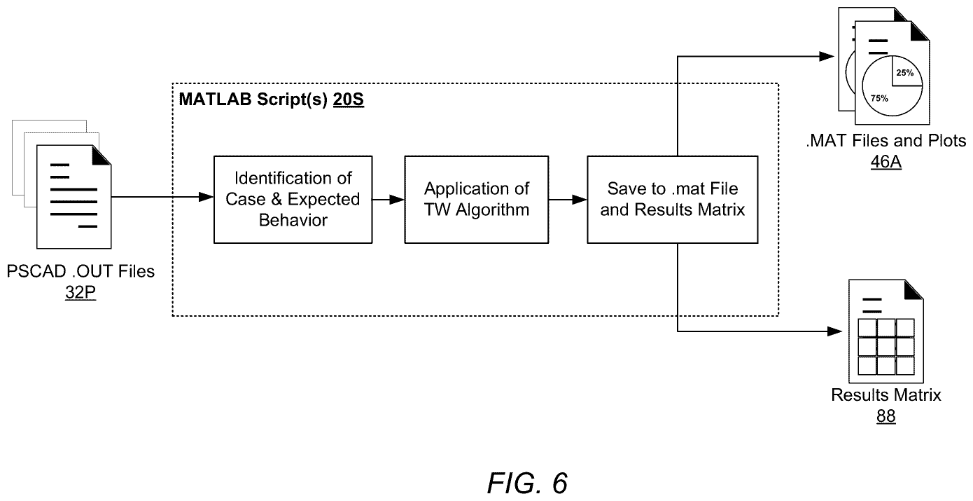

FIG. 5 illustrates processing for performing the simulations according to some embodiments. As shown, the processing includes updating the arrays 35 that hold the permutations of the simulation settings 37 to include desired values for the simulation settings 37 (Block 100). The arrays 35 in some embodiments are updated in this way by a user of the relay configuration equipment 20.

The processing next includes determining whether any system permutations remain (Block 105). If so (YES at Block 105), processing proceeds to updating the electric power system 10 to its next permutation/configuration for simulation (Block 110).

Processing then includes determining whether any DER permutations remain (Block 115). If not, processing reverts back to Block 105. If so (YES at Block 115), processing proceeds to updating the DERs to the next permutation for simulation (Block 120).

Processing then involves determining if any capacitor bank permutations remain (Block 125). If not, processing reverts back to Block 115. If so (YES at Block 125), processing proceeds to updating the capacitor banks to the next permutation for simulation (Block 130).

Processing next involves determining if any fault or switching locations remain (Block 135). If not, processing reverts back to Block 125. If so (YES at Block 135), processing proceeds to setting the next fault location or breaker to switch in the simulation (Block 140).

Processing next includes determining if the event to be simulated is a fault event (Block 145). If not, processing proceeds to updating to the next switching event (Block 147) and running the simulation (Block 180). If so (YES at Block 145), processing proceeds to determining if any fault types remain that have not yet been simulated for this permutation (Block 150). If not (NO at Block 150), processing reverts to Block 135. If so (YES at Block 150), processing proceeds to updating to the next fault type for simulation (Block 155).

Processing then involves determining if any fault resistance permutations remain (Block 160). If not (NO at Block 160), processing reverts to Block 150). If so (YES at Block 160), processing proceeds to updating to the next fault resistance to be simulated (Block 165).

Processing finally includes determining if any inception angle permutations remain (Block 170). If not, processing reverts to Block 160). If so (YES at Block 170), processing moves on to updating to the next fault inception angle to be simulated (Block 175).

The output file 32 is then named for the simulation, e.g., as the concatenation of identifiers for the different permutation parameters (Block 175). The simulation is then run (Block 180).

In some embodiments, the relay configuration equipment 20 implements the above processing with Python scripting, e.g., for automated fault simulation. The relay configuration equipment 20 may do so for instance to automatically run the simulations, e.g., in PSCAD. In these and other embodiments, the script enters a nested loop, starting with the first combination of permutations. The script sets the file name output based on identifiers of active permutations. The script runs the simulation, and the output file 32 for the simulation is saved. The script may then vary the next lowest-level permutation and re-run the simulation, looping its way up to system configuration permutations.

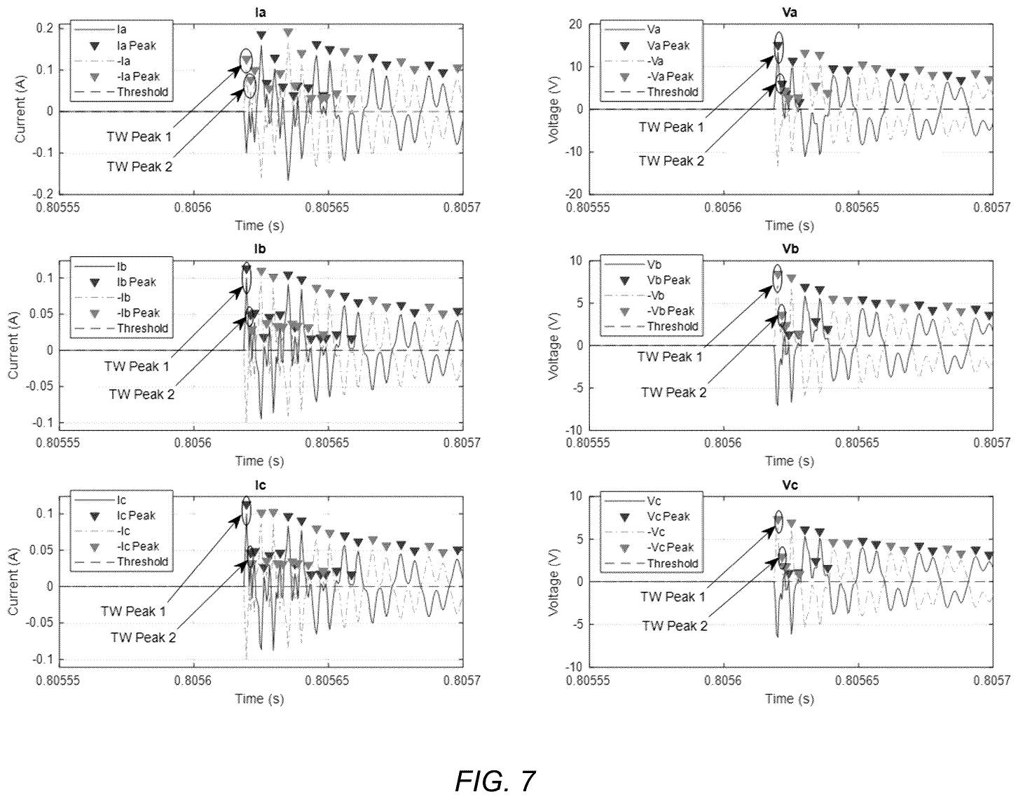

FIG. 6 shows one implementation of some embodiments herein, where the simulations are PSCAD simulations and the output files 32 are PSCAD .OUT files 32P. As shown, after the PSCAD .OUT files 32P are generated from the simulations in PSCAD, e.g., automatically according to Python scripting, the relay configuration equipment 20 executes the matrix laboratory (MATLAB) script(s) 20S shown. The relay configuration equipment 20 in this regard parses the PSCAD .OUT files 32P to identify the events simulated (i.e., the cases) and to determine the expected local responses 26 (i.e., the behavior for directionality and tripping). The relay configuration equipment 20 applies the relay settings 16S under test in order to implement the traveling wave algorithm on each case. The relay configuration equipment 20 then generates comparison data 46 in the form of .MAT files and/or plots 46A, accompanied by a results matrix 88.

More particularly with regard to the traveling wave algorithm, the algorithm in some embodiments extracts characteristics of the traveling waves produced in the simulations and compares those characteristics against those defined in the relay settings 16S as being attributable to a fault event. The characteristics may for instance be defined as a certain threshold, e.g., to ensure the traveling waves are not related to non-fault events, such as load or capacitor bank switching.

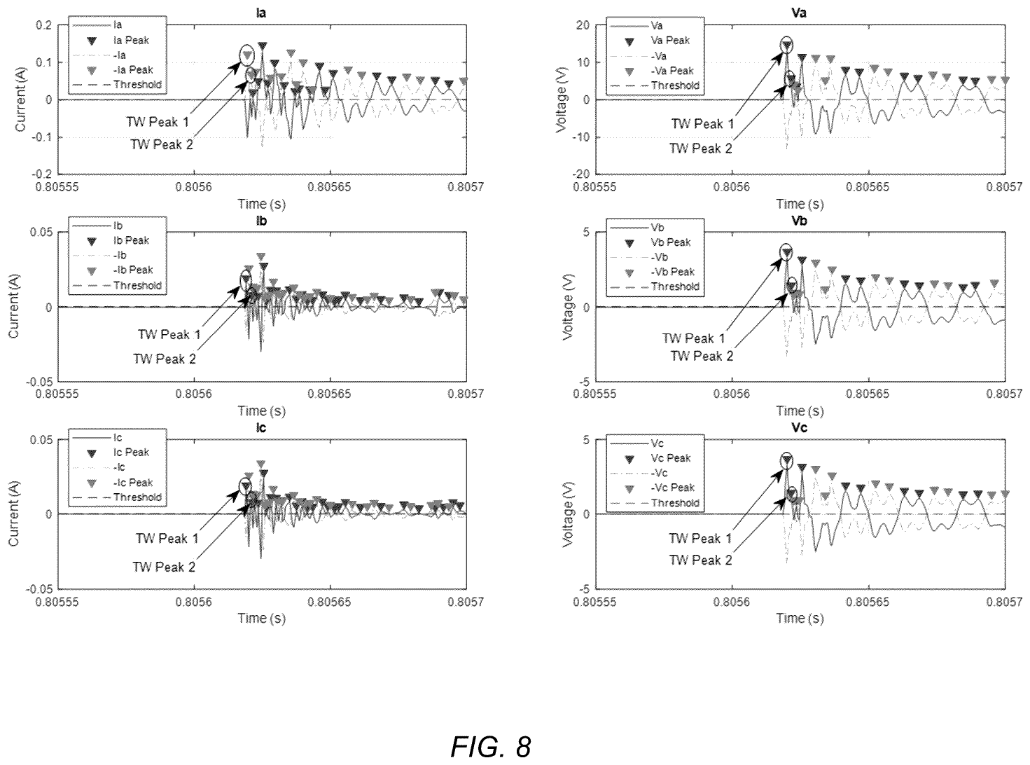

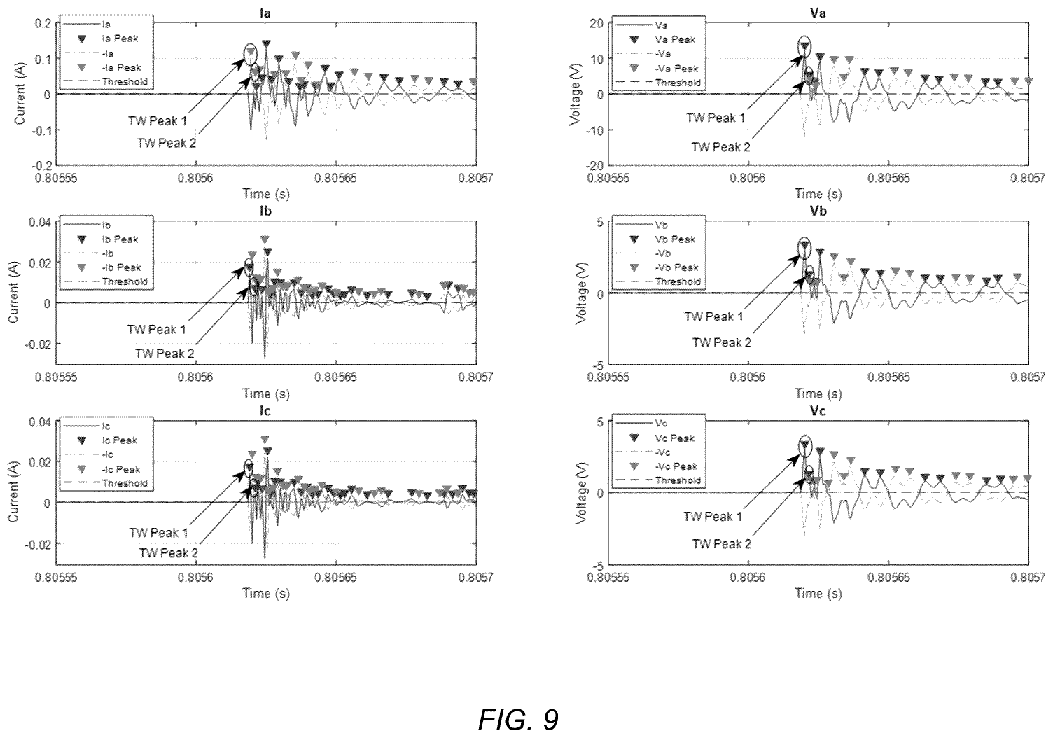

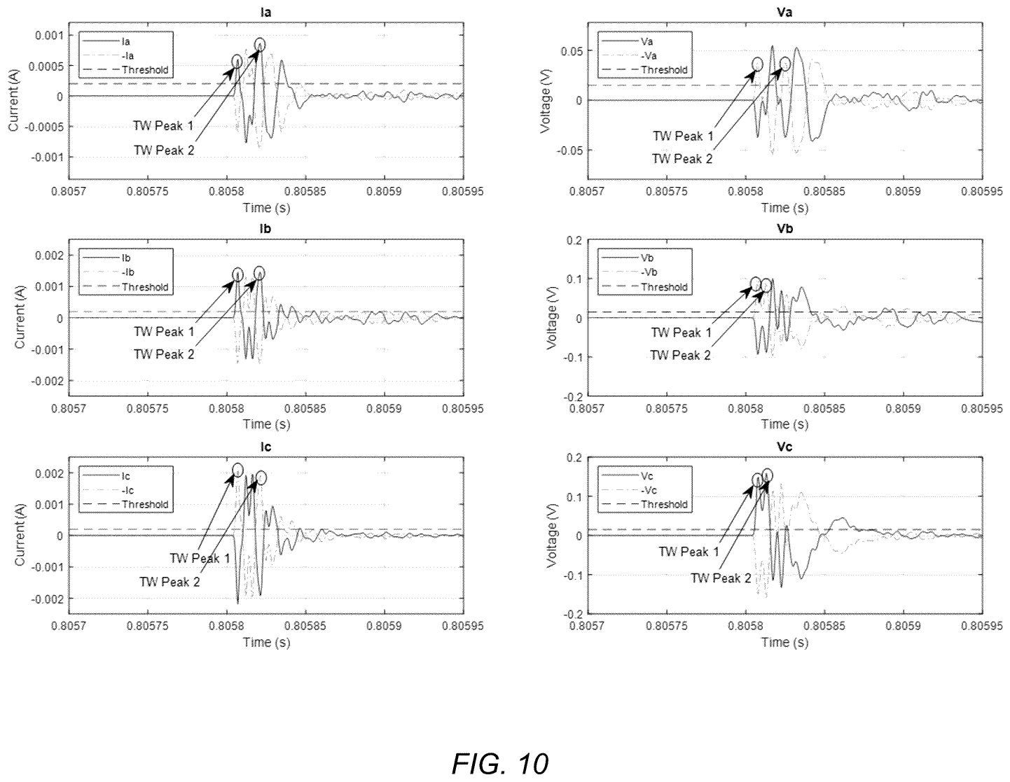

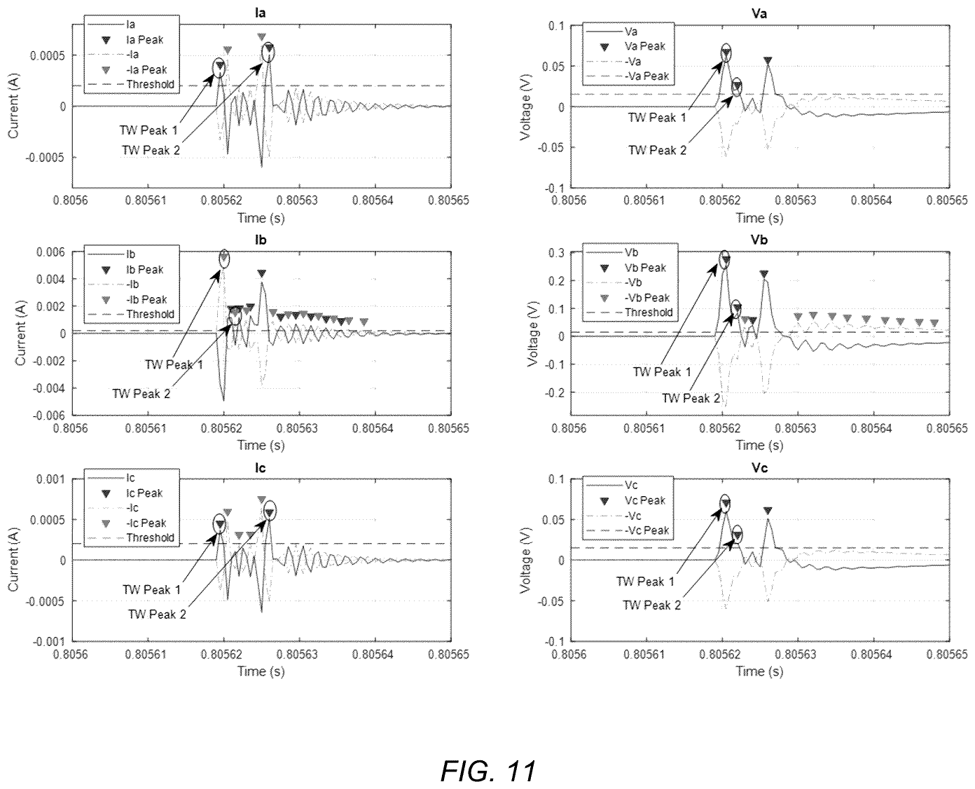

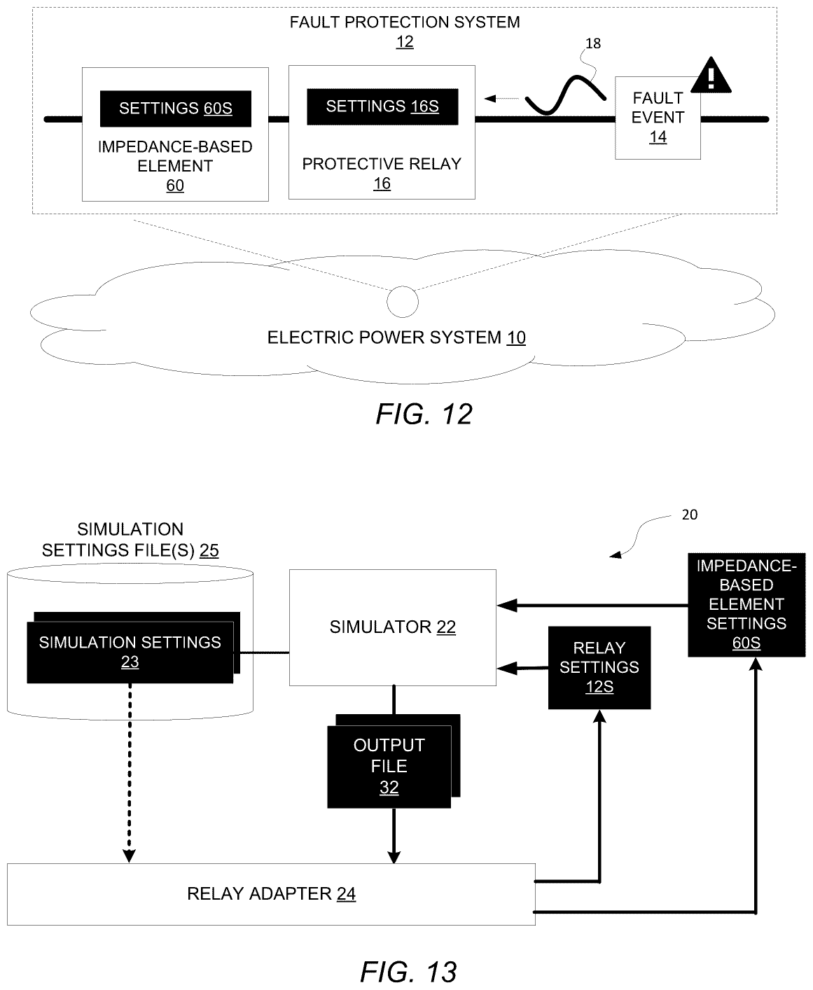

Some embodiments for example are based on the differentiation shown in FIG. 7 through FIG. 11, which show sample traveling wave reflection plots (voltage and current signals) for a three-phase fault (TPH), bolted single-line-to-ground (SLG) fault, resistive SLG fault, capacitor bank switching, and load switching, respectively. The fault is applied close-in and forward to the relay location.

From FIG. 7 to FIG. 11, it can be observed that the first peak of the traveling wave reflection is from the fault location. The second peak can reflect the fault location or the nearest node from the measuring point. Both peaks are observed, and the peak magnitude data is collected to identify a traveling wave-based protection approach that distinguishes faults from those caused by switching loads/capacitor banks in the electric power system 10.

A threshold determines the current and voltage peaks with significant magnitude. Peaks that cross the set threshold are considered to be occurring because of a fault in the electric power system 10. Adjusting the thresholds allows the switching traveling wave peaks to be ignored, and fault traveling wave peaks can be captured. Changing the threshold level can change the dependability and security level balance. The fault can be detected based on either the significant current or voltage traveling wave peaks.

In some embodiments, the traveling waves are monitored at both polarities to determine if the positive or negative peak occurs first. The direction of a fault is determined based on the polarity of the first voltage and current traveling wave peak. If the current and voltage traveling wave peaks have the same polarity, the fault is in the reverse direction with respect to the point of observation and vice versa, as indicated in Table 1.

TABLE 1
TW Directionality

| Polarity of Current | Polarity of Voltage | |
|---|---|---|
| TW 1st Peak | TW 1st Peak | TW Direction |
| Positive | Positive | Reverse |
| Positive | Negative | Forward |
| Negative | Positive | Forward |
| Negative | Negative | Reverse |

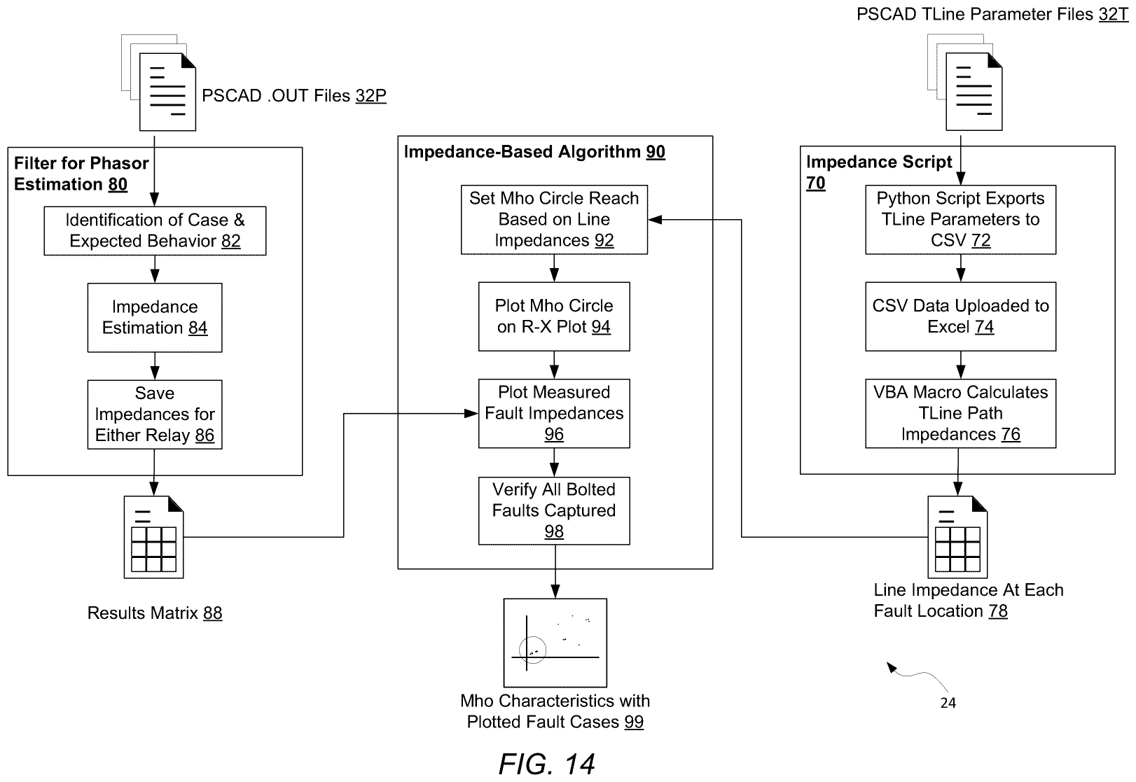

Note, though, that some embodiments herein adapt the relay settings 16S in a way that prioritizes system security over dependability. According to the relay settings 16S as adapted, then, the protective relay 16 does not trip in response to a subset of fault events simulated. That is, the protective relay's settings 16S are set conservatively, to guarantee that the protective relay 16 does not trip in response to non-fault events, albeit at the expense that there may be some fault events that do not trip the protective relay 16. This improves security during fault events. One or more embodiments in this case complement the traveling wave-based protection with impedance-based protection, to capture the subset of fault events whose traveling waves do not trip the protective relay 16. FIG. 12 shows some embodiments in this regard.

As shown in FIG. 12, the fault protection system 12 further includes an impedance-based element 60. The impedance-based element 60 may be referred to as a backup impedance-based element 60 because it backs up the protective relay 16. Some embodiments herein also exploit the simulations of events in the electric power system 10 in order to tailor the backup impedance-based element's settings 60S to complement and backup the protective relay's single-ended traveling wave-based protection.

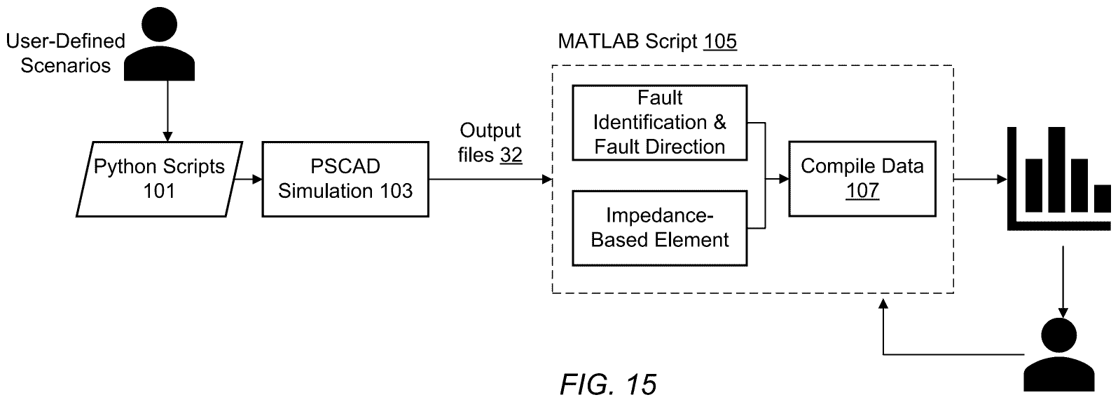

FIG. 13 illustrates additional details in this regard. As shown, the relay adapter 24 of the relay configuration equipment 20 also adapts the impedance-based element settings 60S of the backup impedance-based element 60, based on the output file(s) 32 from the simulations. That is, the relay adapter 24 determines, from the simulations, impedance-based element settings 60S for the backup impedance-based element 60. The impedance-based element settings 60S as determined may specify an impedance attributable to fault events that are to trip the backup impedance-based element 60, where those fault events may include at least those in the subset that do not trip the protective relay 16.

In some embodiments, for example, the output file(s) 32 from the simulations include transmission line (Tline) output files. In this case, the relay adapter 24 estimates, from the transmission line output files, line impedances at locations of respective fault events simulated. The relay adapter 24 then calculates the impedance-based element settings 60S from the estimated line impedances. For example, the transmission line output files may be used to calculate the setting values for the impedance-based relays based on some pre-defined rules and bast practice, e.g., a relay is set to 80% of the impedance calculated from the Tline file. The relay adapter 24 may also verify these impedance-based element settings 60S using the output file(s) 32. For example the relay adapter 24 may estimate, using the output files 32 output from the simulations, fault impedances associated with the respective events simulated, and then verify the impedance-based element settings 60S as a function of the estimated fault impedances.

In some embodiments, the relay adapter 24 determines the impedance-based element settings 60S and the settings 16S of the protective relay 16 jointly or in combination. In one embodiments, the relay adapter 24 determines the settings 16S of the protective relay (e.g., in the form of a threshold on traveling wave reflections) to ensure the security of the traveling wave-based protective relay 16. The relay adapter 24 in doing so may determine the settings 16S for which the electric power system 10 is fully secure and does not trip for any load or capacitor switching events. Jointly, the relay adapter 24 may determine the impedance-based element settings 60S that provide impedance-based protection, to protect the electric power system 10 against the remainder of the faults event, e.g., which may take about one full cycle to operate.

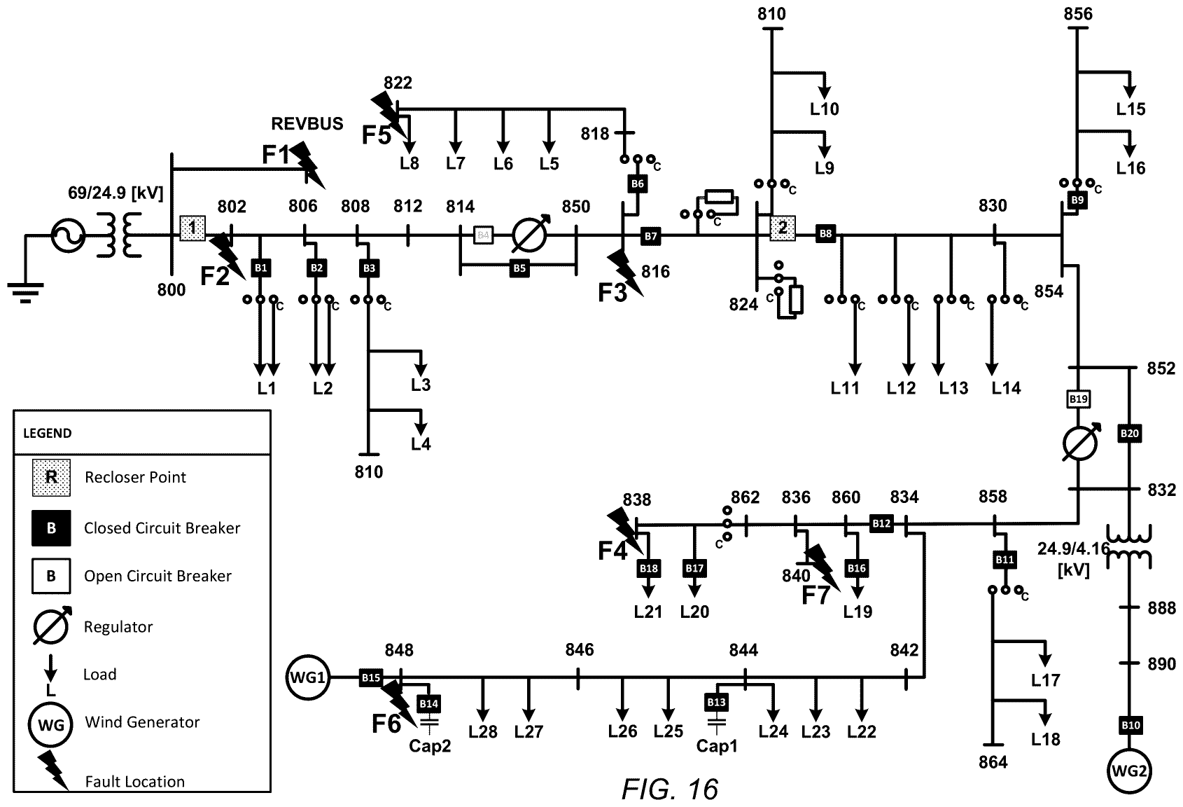

FIG. 14 illustrates additional details of the relay adapter 24 in relevant part for determining the impedance-based element settings 60S according to some embodiments. In one embodiment, the current and voltage signals are exported directly to PSCAD output files for the impedance-based algorithm. The sampling rate in PSCAD for outputs utilized to test the impedance-based element may for example be set to 240.4167 μs for test cases.

As shown, the relay adapter 24 implements scripts 70 to collect the actual line impedance values for each fault location. The scripts 70 may for example be Python and Microsoft Excel Visual Basic (VBA) scripts. In some embodiments, the scripts 70 detect all “TLine” associated output files, e.g., in a PSCAD simulation directory where the output file(s) are PSCAD .OUT files. The scripts 70 then extract the positive-sequence Rsq and Xsq values and convert them into ohms from per-unit. The scripts 70 next save the resistance/reactance for each segment in a .CSV file (Block 72) and upload the CSV data to Excel.

Following this, an Excel VBA macro reads a cell containing a sequence of TLine paths for each fault location (e.g., TLine_1_1, TLine_1_3, etc.). The Excel VBA macro adds up corresponding resistance/reactance values for each segment along the path based on the .CSV output. The Excel VBA macro then calculates and updates a final impedance magnitude and angle cell for each fault location (Block 76).

In some embodiments, in addition to the actual impedance values for each fault location, the impedance of the protected line section for each relay and the zero-sequence compensation factor K0 determined.

In any event, the relay adapter 24 as shown also implements a filter for phasor estimation 80. For example, in some embodiments where the output file(s) 32 are PSCAD .OUT files, the relay adapter 24 passes PSCAD measurements from all simulations into a MATLAB Cosine filter implementation that also estimates impedances. In one such embodiment, the PSCAD output channel plot step is set to 260.4167-μs (representing 64 samples per cycle at 60-Hz) for all simulations conducted to evaluate the traveling wave algorithm. This rate represents the sampling rate of the impedance-based element. The .OUT files are passed as inputs into the phasor estimation scheme utilizing a Cosine filter algorithm, which also calculates the impedances and returns them as outputs in the form of a results matrix 88. In this regard, the filter for phasor estimation 80 identifies the case and expected behavior of each simulation from the PSCAD .OUT files 32P (Block 82), estimates impedances (Block 84), and saves the impedances for in the form of a results matrix 88 (Block 86). Note that, in some embodiments, the phasor estimation may be performed with the values of the samples 1.5-cycle after the switching/fault inception time to reflect the conventional impedance-based element speeds.

With the results matrix 88 and the line impedances at each fault location 78, an impedance-based algorithm 90 creates a mho characteristic 99 in MATLAB, e.g., set based on the primary line impedance data with all the estimated impedances plotted. For example, the algorithm 90 sets the Mho circle reach based on the line impedances (Block 92), plots the Mho circle on an R-X plot (Block 94), plots measured fault impedances (Block 96), and verifies all bolted faults are captured within the Mho circle (Block 98). Here, if dots are inside the Mho, it means the relay would trip; if dots are outside the Mho, it means relay does not trip. Embodiments herein target all fault cases being inside the Mho circle and all non-fault cases being outside the Mho circle. In one embodiment, then, the relay Mho characteristic (offset circle) is formed and plotted, where the diameter of the circle is equal to the calculated setting.

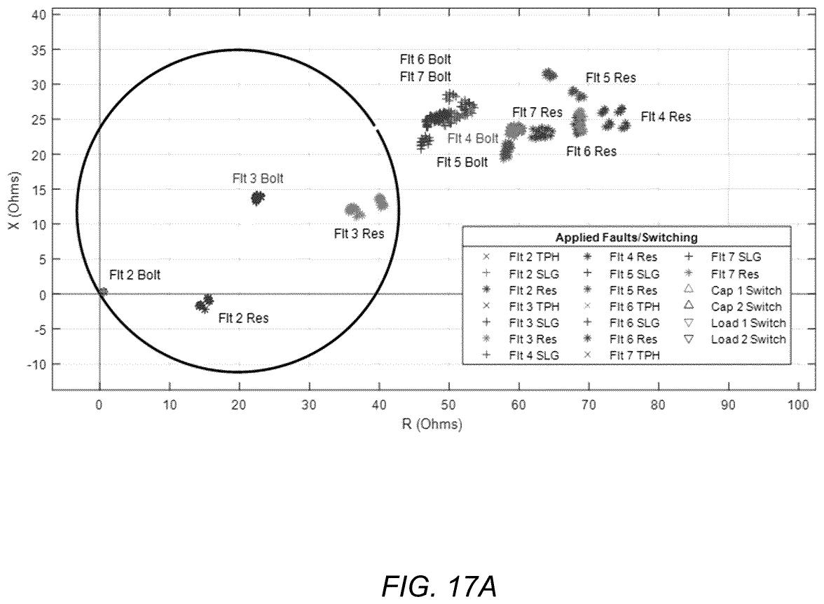

Note that, in some embodiments, to complete the automated process, the PSCAD and MATLAB processes are integrated as shown in FIG. 15. In these embodiments, a user modifies Python scripts 101 to select parameters for simulations to run, where the Python scripts define and exemplify the simulation settings 23 in FIGS. 2 and 3. The PSCAD simulations are performed and produce output files 32 in the form of text files representing voltage, current, and traveling wave data. These output files are assigned identifiable file names. A MATLAB script 105 reads the output files 32, applies the traveling wave algorithm and the impedance-based algorithm to each case, and compares the simulation results with the expected operation. The results are compiled into compile data 107, and analyzed. In some embodiments, the results are reviewed and/or verified by the user, who may then fine-tune the MATLAB script 105 for a re-run in another iteration.

Although embodiments above were illustrated for a cosine filter, embodiments may alternatively use a Discrete Fourier Transform (DFT) filter.

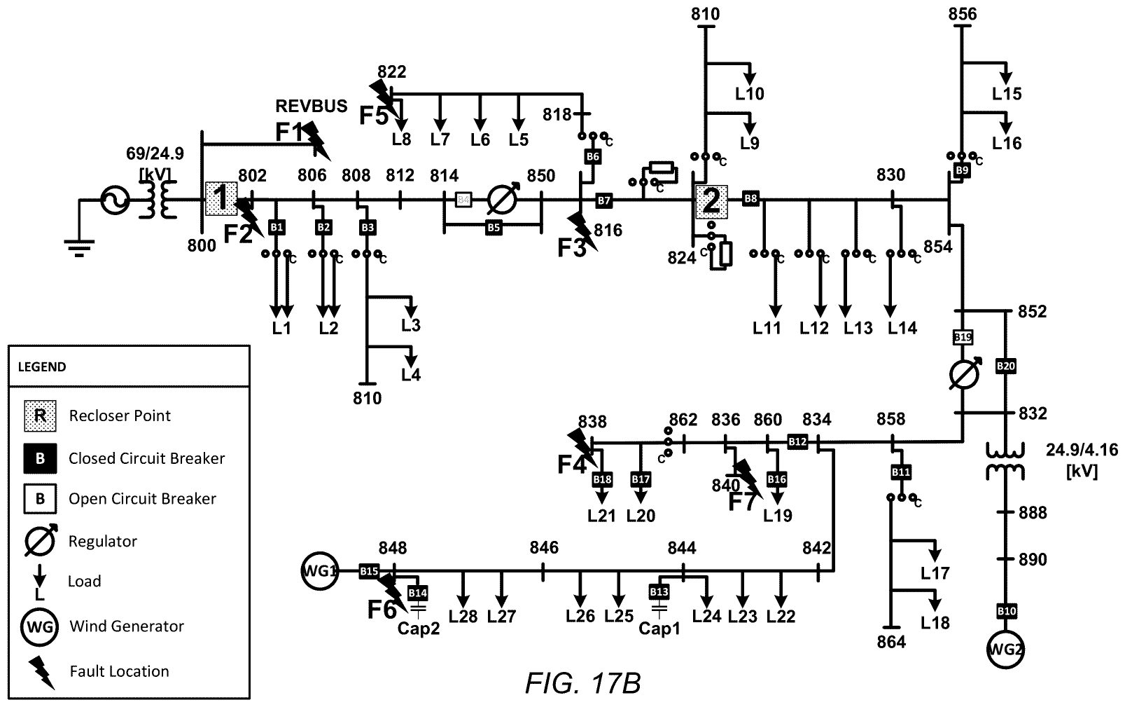

Consider now a concrete example. FIG. 16 shows the test system and the location of the simulated faults in the example. Table 2 summarizes the security and dependability calculations for the simulations done, considering the impact of the voltage regulator being in and out of service.

TABLE 2
Summary of Security and Dependability Calculations for TW Element

| | | | DEPENDABILITY | | | | | |
|---|---|---|---|---|---|---|---|---|
| | | | Recloser 1 | | | Recloser 2 | | |
| | | | | Bolted | Resistive | | Bolted | Resistive |
| | SECURITY | | TPH | SLG | SLG | TPH | SLG | SLG |
| SCENARIO | Recloser 1 | Recloser 2 | Faults | Faults | Faults | Faults | Faults | Faults |
| Voltage | 100% | 100% | 28% | 13% | 12% | 27% | 13% | 12% |
| regulator 2 in | | | | | | | | |
| circuit- | | | | | | | | |
| Scenario 1 | | | | | | | | |
| Voltage | 100% | 100% | 28% | 13% | 12% | 53% | 52% | 52% |
| regulator 2 in | | | | | | | | |
| circuit- | | | | | | | | |
| Scenario 2 | | | | | | | | |
| Voltage | 100% | 100% | 88% | 70% | 69% | 88% | 84% | 83% |
| regulator 2 in | | | | | | | | |
| circuit- | | | | | | | | |
| Scenario 3 | | | | | | | | |
| Voltage | 100% | 100% | 88% | 70% | 69% | 88% | 89% | 89% |
| regulator 2 in | | | | | | | | |
| circuit- | | | | | | | | |
| Scenario 4 | | | | | | | | |
| Voltage | 100% | 100% | 33% | 13% | 12% | 27% | 12% | 12% |
| regulator 2 out | | | | | | | | |
| of circuit- | | | | | | | | |
| Scenario 1 | | | | | | | | |
| Voltage | 100% | 100% | 33% | 13% | 12% | 53% | 52% | 52% |
| regulator 2 out | | | | | | | | |
| of circuit- | | | | | | | | |
| Scenario 2 | | | | | | | | |
| Voltage | 100% | 100% | 88% | 64% | 62% | 88% | 81% | 81% |
| regulator 2 out | | | | | | | | |
| of circuit- | | | | | | | | |
| Scenario 3 | | | | | | | | |
| Voltage | 100% | 100% | 88% | 64% | 62% | 88% | 86% | 86% |
| regulator 2 out | | | | | | | | |
| of circuit- | | | | | | | | |
| Scenario 4 | | | | | | | | |

In Scenario 1 of Table 2, it is assumed that (1) the Operator/settings do NOT prevent traveling wave-based elements from tripping for capacitor bank switching; and (2) the traveling wave-based element has to detect reverse faults.

In Scenario 2 of Table 2, it is assumed that (1) the Operator/settings do NOT prevent traveling wave-based elements from tripping for capacitor bank switching; and (2) the TW-based element does NOT have to detect reverse faults.

In Scenario 3 of Table 2, it is assumed that: (1) the Operator/settings prevent TW-based elements from tripping for capacitor bank switching; and (2) the traveling wave based element has to detect reverse faults.

In Scenario 4, it is assumed that: (1) the Operator/settings prevent traveling wave-based elements from tripping for capacitor bank switching; and (2) the traveling wave-based element does NOT have to detect reverse faults.

The sample results for the impedance-based element are given here. For each simulation scenario that was evaluated for the traveling wave-based algorithm, an equivalent simulation was run at a lower sampling rate to be inputted into the impedance-based algorithm to evaluate whether the impedance-based element would be a viable backup for cases where the traveling wave-based method is unable to detect an in-zone fault.

The following sections describe the evaluation results of the proposed impedance-based element as a reliable backup to the traveling wave-based element for all fault scenarios. The settings were evaluated by analyzing fault impedances when Regulator 2 was in circuit and when it was bypassed.

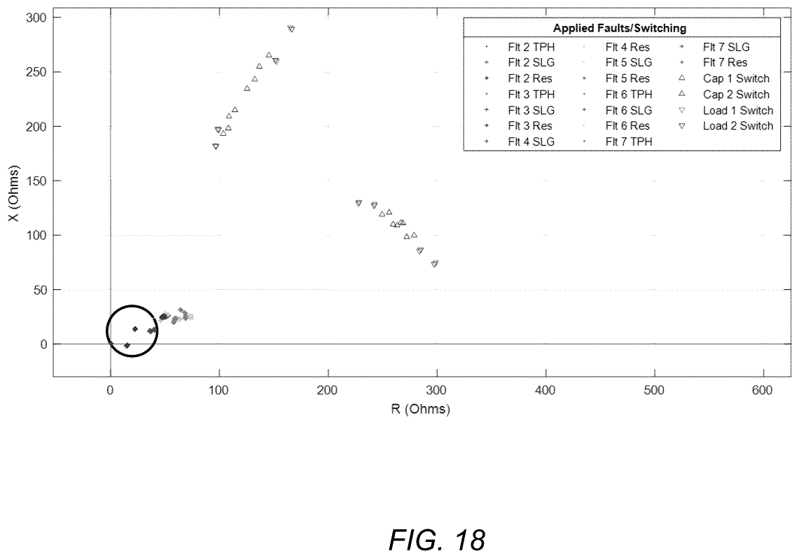

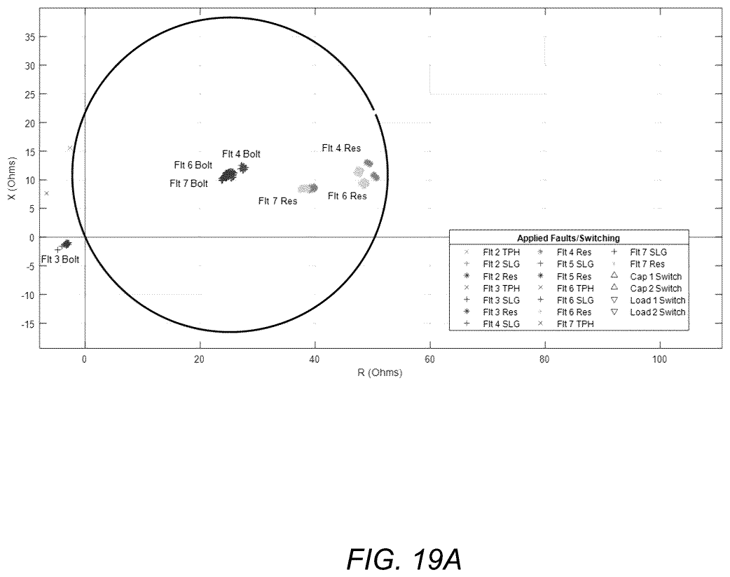

All relevant faults that occur, as seen by Recloser 1 when Regulator 2 is in-circuit, are plotted in FIG. 17A, alongside a reference of all fault locations in FIG. 17B. The mho characteristic with the proposed reach and relay characteristic angle (RCA) is shown. Note that ‘Bolt’ implies a bolted fault and ‘Res’ implies a 20-Ω resistive SLG fault. A zoomed-out plot to show out-of-zone faults and switching events is shown in FIG. 18.

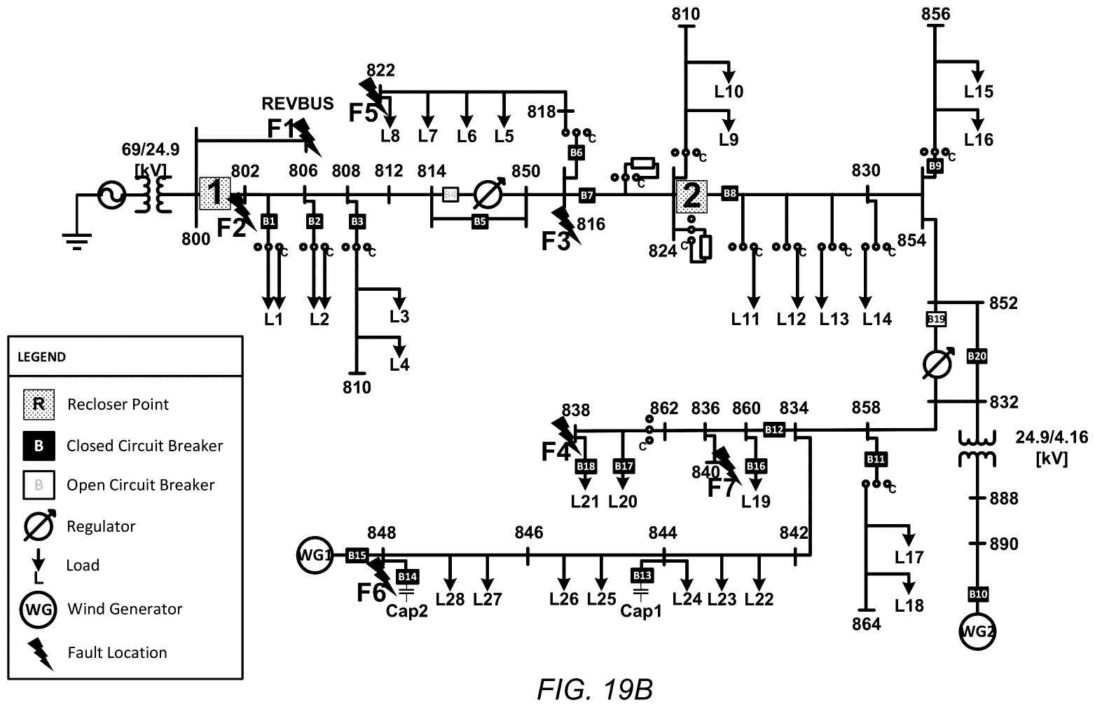

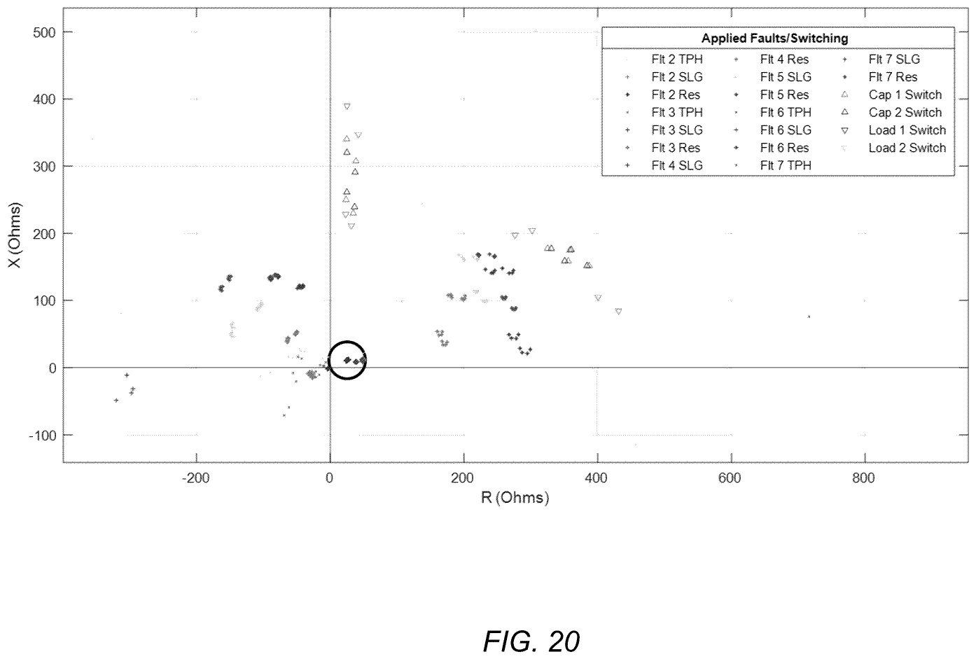

The corresponding plots for Recloser 2 are shown in FIGS. 19A/19B and FIG. 20, respectively.

FIG. 17A shows Recloser 1's impedance-based element can pick up all bolted and 20-Ω resistive faults at fault locations 2 and 3 but not at the remaining fault locations on the line. Faults at locations 4, 6, and 7 will be covered by the second recloser, whereas a fault on the single-phase lateral (location 5) can be caught by fuse protection. Capacitor and load switching scenarios are sufficiently distant from the mho circle (FIG. 17A) and will not cause misoperations.

Similarly, in FIG. 19A, it is seen that Recloser 2 will operate for all bolted and 20-Ω resistive faults at locations 4, 6, and 7. Reverse faults are seen in FIG. 20, along with the capacitor and load switching events, to be distant from the mho circle due to the low current value seen by the recloser in the opposite direction, particularly when the downstream DERs are removed.

Therefore, either recloser's impedance-based element will capture all bolted and 20-Ω resistive faults and are not expected to misoperate for non-fault events.

Table 3 summarizes the security and dependability calculations when both the traveling wave and impedance-based elements (when utilized in parallel) would form the complete proposed scheme.

TABLE 3
Summary of Security and Dependability Calculations-TW and Impedance-Based Element

| | | | DEPENDABILITY | | | | | |
|---|---|---|---|---|---|---|---|---|
| | | | Recloser 1 | | | Recloser 2 | | |
| | | | | Bolted | Resistive | | Bolted | Resistive |
| | SECURITY | | TPH | SLG | SLG | TPH | SLG | SLG |
| SCENARIO | Recloser 1 | Recloser 2 | Faults | Faults | Faults | Faults | Faults | Faults |
| Voltage | 100% | 100% | 28% | 13% | 12% | 27% | 13% | 12% |
| regulator 2 in | | | | | | | | |
| circuit- | | | | | | | | |
| Scenario 1 | | | | | | | | |
| Voltage | 100% | 100% | 28% | 13% | 12% | 53% | 52% | 52% |
| regulator 2 in | | | | | | | | |
| circuit- | | | | | | | | |
| Scenario 2 | | | | | | | | |
| Voltage | 100% | 100% | 88% | 70% | 69% | 88% | 84% | 83% |
| regulator 2 in | | | | | | | | |
| circuit- | | | | | | | | |
| Scenario 3 | | | | | | | | |
| Voltage | 100% | 100% | 88% | 70% | 69% | 88% | 89% | 89% |
| regulator 2 in | | | | | | | | |
| circuit- | | | | | | | | |
| Scenario 4 | | | | | | | | |
| Voltage | 100% | 100% | 33% | 13% | 12% | 27% | 12% | 12% |
| regulator 2 out | | | | | | | | |
| of circuit- | | | | | | | | |
| Scenario 1 | | | | | | | | |
| Voltage | 100% | 100% | 33% | 13% | 12% | 53% | 52% | 52% |
| regulator 2 out | | | | | | | | |
| of circuit- | | | | | | | | |
| Scenario 2 | | | | | | | | |
| Voltage | 100% | 100% | 88% | 64% | 62% | 88% | 81% | 81% |
| regulator 2 out | | | | | | | | |
| of circuit- | | | | | | | | |
| Scenario 3 | | | | | | | | |
| Voltage | 100% | 100% | 88% | 64% | 62% | 88% | 86% | 86% |
| regulator 2 out | | | | | | | | |
| of circuit- | | | | | | | | |
| Scenario 4 | | | | | | | | |
| Impedance- | 100% | 100% | 100% | 84% | 84% | 100% | 100% | 100% |
| based element | | | | | | | | |
| Impedance- | 100% | 100% | 100% | 89% | 89% | 100% | 100% | 100% |
| based and TW | | | | | | | | |
| element | | | | | | | | |
| Impedance- | 100% | 100% | 100% | 100% | 100% | 100% | 100% | 100% |
| based and TW | | | | | | | | |
| element | | | | | | | | |
| (Excluding fuse- | | | | | | | | |
| protected single- | | | | | | | | |
| phase laterals) | | | | | | | | |

Generally, then, embodiments herein include a traveling wave (TW) protection algorithm, developed and validated using Electromagnetic Transients, including Direct Current (EMTDC) simulation software, and enhanced using an impedance-based method. The voltage and current traveling waves are captured and assessed against an adaptive threshold to distinguish faults and switching cases reliably and detect the faults' direction. An impedance-based method is developed to enhance the dependability of the proposed protection algorithm to achieve a fully reliable protection scheme for high-speed distribution line tripping without using communication systems. An automation-based data-driven validation method is developed and executed to test the algorithm against a series of fault and switching cases and operating scenarios to assess its suitability for high-speed tripping and potential future field trial deployment.

Certain embodiments may provide one or more of the following technical advantage(s): (1) fast clearing of faults in the distribution system; (2) the scheme does not require communication, making it less complicated and more cost-efficient than the existing schemes; (3) it does not depend on the system's configurations and parameters and is applicable to different systems; (4) it is fully secure and dependable; (5) the data-driven feature of the method allows its application in complicated and complex systems; and (6) it is adaptive and adjustable by allowing the user to change the settings.

Some embodiments accordingly provide advanced relay protection algorithms to quickly detect and disconnect faulted circuits where traditional protection is slow or ineffective. Two main different protection techniques, including traveling wave and impedance-based, have been developed to form a new fully reliable scheme allowing high-speed detection and clearing of various faults under different system configurations.

Some embodiments herein generally provide a data-driven approach to configuring a protective relay to use traveling waves for fast and sensitive fault detection. This data-driven approach uses a large amount of data, captured under various system conditions and model permutations, to determine the most appropriate settings for protective relays to locally recognize traveling waves attributable to a fault event. Such single-ended traveling wave-based protection proves advantageous for fast protection of the electric power system 10 without using communication systems. In doing so, some embodiments advantageously alleviate the risk of wildfire and reduce arc flash energy.

Furthermore, one or more embodiments complement the traveling wave-based fault detection algorithm with an impedance-based algorithm that is used in parallel. This hybrid approach that exploits both traveling wave-based fault detection and impedance-based fault detection advantageously increases protection system reliability when the traveling wave-based fault detection cannot detect certain faults.

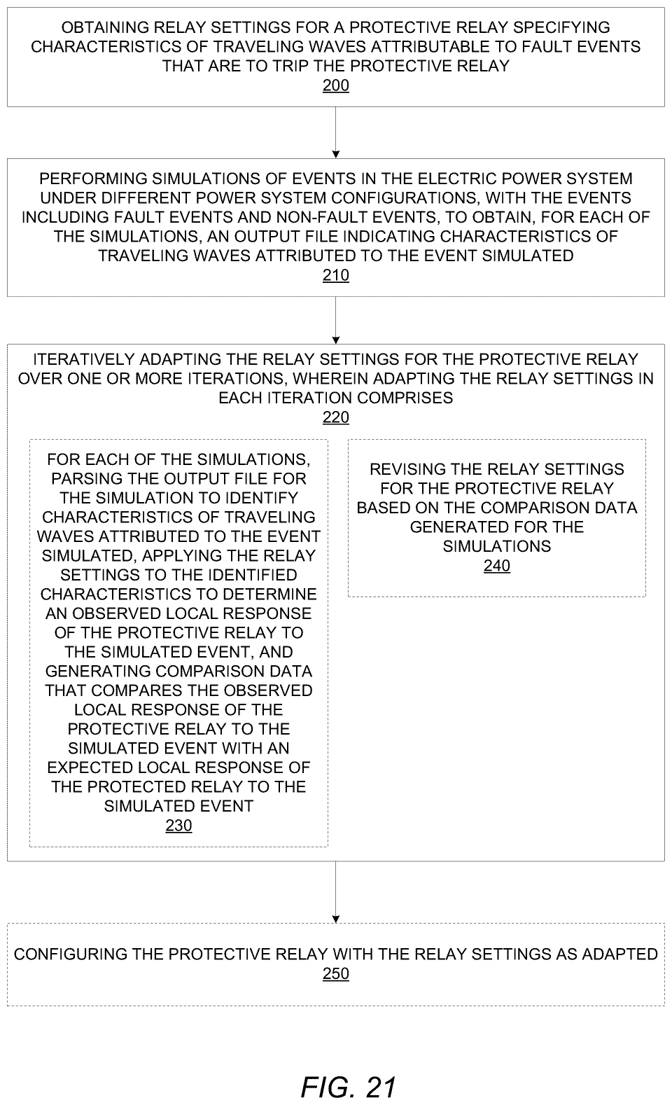

In view of the modifications and variations herein, FIG. 21 depicts a method performed by an electric power system 10 in accordance with particular embodiments, with reference numbers referring to FIGS. 2 and 3. The method includes obtaining relay settings 16S for a protective relay 16 specifying characteristics 36 of traveling waves 18 attributable to fault events 14 that are to trip the protective relay 16 (Block 200). The method also includes performing simulations of events in the electric power system 10 under different power system configurations, with the events including fault events 14 and non-fault events (Block 210). In some embodiments, performing the simulation of events results in obtaining, for each of the simulations, an output file 32 indicating characteristics of traveling waves 18 attributed to the event simulated.

The method also includes iteratively adapting the relay settings 16S for the protective relay 16, e.g., over one or more iterations (Block 220). In some embodiments, adapting the relay settings 16S in each iteration comprises, for each of the simulations, parsing the output file 32 for the simulation to identify characteristics 36 of traveling waves 18 attributed to the event simulated, applying the relay settings 16S to the identified characteristics 36 to determine an observed local response 26 of the protective relay 16 to the simulated event, and generating comparison data that compares the observed local response 26 of the protective relay 16 to the simulated event with an expected local response 42 of the protected relay to the simulated event (Block 230). In some embodiments, adapting the relay settings 16S in each iteration also comprises revising the relay settings 16S for the protective relay 16 based on the comparison data generated for the simulations (Block 240).

In some embodiments, the method also includes configuring the protective relay 16 with the relay settings 16S as adapted (Block 250).

Embodiments herein also include corresponding apparatuses. Embodiments herein for instance include relay configuration equipment 20 configured to perform any of the steps of any of the embodiments described above.

Embodiments also include relay configuration equipment 20 comprising processing circuitry and power supply circuitry. The processing circuitry is configured to perform any of the steps of any of the embodiments described above. The power supply circuitry is configured to supply power to the relay configuration equipment 20.

Embodiments further include relay configuration equipment 20 comprising processing circuitry. The processing circuitry is configured to perform any of the steps of any of the embodiments described above.

Embodiments further include relay configuration equipment 20 comprising processing circuitry and memory. The memory contains instructions executable by the processing circuitry whereby the relay configuration equipment 20 is configured to perform any of the steps of any of the embodiments described above.

More particularly, the relay configuration equipment 20 described above may perform the methods herein and any other processing by implementing any functional means, modules, units, or circuitry. In one embodiment, for example, the relay configuration equipment 20 comprises respective circuits or circuitry configured to perform the steps shown in the method figures. The circuits or circuitry in this regard may comprise circuits dedicated to performing certain functional processing and/or one or more microprocessors in conjunction with memory. For instance, the circuitry may include one or more microprocessor or microcontrollers, as well as other digital hardware, which may include digital signal processors (DSPs), special-purpose digital logic, and the like. The processing circuitry may be configured to execute program code stored in memory, which may include one or several types of memory such as read-only memory (ROM), random-access memory, cache memory, flash memory devices, optical storage devices, etc. Program code stored in memory may include program instructions for carrying out one or more of the techniques described herein, in several embodiments. In embodiments that employ memory, the memory stores program code that, when executed by the one or more processors, carries out the techniques described herein.

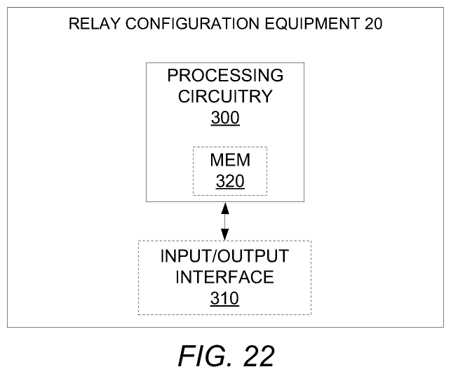

FIG. 22 illustrates relay configuration equipment 20 as implemented in accordance with one or more embodiments. As shown, the relay configuration equipment 20 includes processing circuitry 300. The processing circuitry 300 is configured to perform processing described above, e.g., in FIG. 21, such as by executing instructions stored in memory 320. The processing circuitry 300 in this regard may implement certain functional means, units, or modules. In some embodiments, the relay configuration equipment 20 further comprises an input/output interface 310. The input/output interface 310 may for instance be configured to receive input for processing herein and/or to output one or more outputs of the processing herein.

Those skilled in the art will also appreciate that embodiments herein further include corresponding computer programs.

A computer program comprises instructions which, when executed on at least one processor of relay configuration equipment 20, cause the relay configuration equipment 20 to carry out any of the respective processing described above. A computer program in this regard may comprise one or more code modules corresponding to the means or units described above.

Embodiments further include a carrier containing such a computer program. This carrier may comprise one of an electronic signal, optical signal, radio signal, or computer readable storage medium.

In this regard, embodiments herein also include a computer program product stored on a non-transitory computer readable (storage or recording) medium and comprising instructions that, when executed by a processor of relay configuration equipment 20, cause the relay configuration equipment 20 to perform as described above.

Embodiments further include a computer program product comprising program code portions for performing the steps of any of the embodiments herein when the computer program product is executed by relay configuration equipment 20. This computer program product may be stored on a computer readable recording medium.

In certain embodiments, some or all of the functionality described herein may be provided by processing circuitry executing instructions stored on in memory, which in certain embodiments may be a computer program product in the form of a non-transitory computer-readable storage medium. In alternative embodiments, some or all of the functionality may be provided by the processing circuitry without executing instructions stored on a separate or discrete device-readable storage medium, such as in a hard-wired manner. In any of those particular embodiments, whether executing instructions stored on a non-transitory computer-readable storage medium or not, the processing circuitry can be configured to perform the described functionality. The benefits provided by such functionality are not limited to the processing circuitry alone or to other components of the computing device, but are enjoyed by the computing device as a whole.

What is claimed is:

1. A method for single-ended traveling wave-based protection of an electric power system, the method comprising:
obtaining relay settings for a protective relay specifying characteristics of traveling waves attributable to fault events that are to trip the protective relay;
performing simulations of events in the electric power system under different power system configurations, with the events including fault events and non-fault events, to obtain, for each of the simulations, an output file indicating characteristics of traveling waves attributed to the event simulated; and
iteratively adapting the relay settings for the protective relay over one or more iterations, wherein adapting the relay settings in each iteration comprises:
for each of the simulations, parsing the output file for the simulation to identify characteristics of traveling waves attributed to the event simulated, applying the relay settings to the identified characteristics to determine an observed local response of the protective relay to the simulated event, and generating comparison data that compares the observed local response of the protective relay to the simulated event with an expected local response of the protective relay to the simulated event; and
revising the relay settings for the protective relay based on the comparison data generated for the simulations.

2. The method of claim 1, wherein a simulation settings file specifies, for each of the simulations, the event to be simulated as well as the power system configuration under which the simulation is to be performed, wherein performing the simulations comprises, for each of the simulations:
obtaining settings specific to the simulation by parsing the simulation settings file;
performing the simulation with the obtained settings;
determining, from the obtained settings, a simulation identifier that identifies the simulation; and
labeling the output file for the simulation with the simulation identifier.

3. The method of claim 2, wherein, for each of the simulations, adapting the relay settings in each iteration further comprises determining the expected local response of the protective relay to the simulated event from how the output file for the simulation is labeled.

4. The method of claim 2, wherein labeling the output file for the simulation with the simulation identifier comprises naming the output file for the simulation with the simulation identifier.

5. The method of claim 2, wherein the simulation settings file includes an array for each simulation, wherein the array for each simulation includes a combination of settings identifiers that comprises two or more event setting identifiers for different types of event settings and/or two or more system configuration setting identifiers for different types of system configuration settings, wherein each event settings identifier of a given type identifies one out of multiple candidate preconfigured event settings of the given type, and wherein each system configuration setting identifiers identifies one out of multiple candidate preconfigured system configuration settings of the given type.

6. The method of claim 5, wherein the different types of event settings include at least a location setting specifying a location of an event and an event type setting specifying a type of an event, and wherein the different types of system configuration settings include at least a load setting specifying a loading on the electric power system and a distributed energy resource setting specifying a presence and/or type of distributed energy resources in the electric power system.

7. The method of claim 5, wherein determining the simulation identifier for each simulation comprises generating the simulation identifier by concatenating the settings identifiers included in the array for the simulation.

8. The method of claim 1, wherein characteristics of traveling waves include:
a peak value and/or polarity of a current wave; and/or
a peak value and/or polarity of a voltage wave.

9. The method of claim 1, wherein the simulations are electromagnetic transients program simulations.

10. The method of claim 1, wherein adapting the relay settings comprises adapting the relay settings as needed to maximize a number of simulated fault events that the protective relay trips in response to, while preventing the protective relay from tripping in response to any simulated non-fault event.

11. The method of claim 10, wherein, according to the relay settings as adapted, the protective relay does not trip in response to a subset of fault events simulated, and wherein the method further comprises determining, from the simulations, impedance-based element settings for a backup impedance-based element specifying an impedance attributable to fault events in the subset that are to trip the backup impedance-based element.

12. The method of claim 11, wherein determining the impedance-based element settings comprises:
estimating, from transmission line output files output from the simulations, line impedances at locations of respective fault events simulated; and
calculating the impedance-based element settings from the estimated line impedances.

13. The method of claim 12, wherein determining the impedance-based element settings further comprises:
estimating, using the output files output from the simulations, fault impedances associated with the respective events simulated; and
verifying the impedance-based element settings as a function of the estimated fault impedances.

14. The method of claim 1, further comprising configuring the protective relay with the relay settings as adapted.

15. A non-transitory computer-readable medium on which is stored instructions that, when executed by a processor, cause the processor to:
obtain relay settings for a protective relay specifying characteristics of traveling waves attributable to fault events that are to trip the protective relay;
perform simulations of events in the electric power system under different power system configurations, with the events including fault events and non-fault events, to obtain, for each of the simulations, an output file indicating characteristics of traveling waves attributed to the event simulated; and
iteratively adapt the relay settings for the protective relay over one or more iterations, wherein adapting the relay settings in each iteration comprises:
for each of the simulations, parsing the output file for the simulation to identify characteristics of traveling waves attributed to the event simulated, applying the relay settings to the identified characteristics to determine an observed local response of the protective relay to the simulated event, and generating comparison data that compares the observed local response of the protective relay to the simulated event with an expected local response of the protective relay to the simulated event; and
revising the relay settings for the protective relay based on the comparison data generated for the simulations.

16. The non-transitory computer-readable medium of claim 15, wherein a simulation settings file specifies, for each of the simulations, the event to be simulated as well as the power system configuration under which the simulation is to be performed, wherein the instructions, when executed by the processor, cause the processor to perform the simulations by, for each of the simulations:
obtaining settings specific to the simulation by parsing the simulation settings file;
performing the simulation with the obtained settings;
determining, from the obtained settings, a simulation identifier that identifies the simulation; and
labeling the output file for the simulation with the simulation identifier.

17. The non-transitory computer-readable medium of claim 16, wherein the instructions, when executed by the processor, cause the processor to, for each of the simulations, parse the output file for the simulation to identify characteristics of traveling waves attributed to the event simulated by identifying the characteristics of traveling waves attributed to the event simulated from how the output file is labeled.

18. The non-transitory computer-readable medium of claim 16, wherein the instructions, when executed by the processor, cause the processor to label the output file for the simulation with the simulation identifier by naming the output file for the simulation with the simulation identifier.

19. The non-transitory computer-readable medium of claim 16, wherein the simulation settings file includes an array for each simulation, wherein the array for each simulation includes a combination of settings identifiers that comprises two or more event setting identifiers for different types of event settings and/or two or more system configuration setting identifiers for different types of system configuration settings, wherein each event settings identifier of a given type identifies one out of multiple candidate preconfigured event settings of the given type, and wherein each system configuration setting identifiers identifies one out of multiple candidate preconfigured system configuration settings of the given type.

20. The non-transitory computer-readable medium of claim 19, wherein the different types of event settings include at least a location setting specifying a location of an event and an event type setting specifying a type of an event, and wherein the different types of system configuration settings include at least a load setting specifying a loading on the electric power system and a distributed energy resource setting specifying a presence and/or type of distributed energy resources in the electric power system.

21. The non-transitory computer-readable medium of claim 19, wherein the instructions, when executed by the processor, cause the processor to generate the simulation identifier by concatenating the settings identifiers included in the array for the simulation.

22. The non-transitory computer-readable medium of claim 15, wherein characteristics of traveling waves include:
a peak value and/or polarity of a current wave; and/or
a peak value and/or polarity of a voltage wave.

23. The non-transitory computer-readable medium of claim 15, wherein the simulations are electromagnetic transients program simulations.

24. The non-transitory computer-readable medium of claim 15, wherein the instructions, when executed by the processor, cause the processor to adapt the relay settings as needed to maximize a number of simulated fault events that the protective relay trips in response to, while preventing the protective relay from tripping in response to any simulated non-fault event.

25. The method of claim 24, wherein, according to the relay settings as adapted, the protective relay does not trip in response to a subset of fault events simulated, and wherein the instructions, when executed by the processor, cause the processor to determine, from the simulations, impedance-based element settings for a backup impedance-based element specifying an impedance attributable to fault events in the subset that are to trip the backup impedance-based element.

26. The method of claim 25, wherein the instructions, when executed by the processor, cause the processor to determine the impedance-based element settings by:
estimating, from transmission line output files output from the simulations, line impedances at locations of respective fault events simulated; and
calculating the impedance-based element settings from the estimated line impedances.

27. The method of claim 26, wherein the instructions, when executed by the processor, cause the processor to determine the impedance-based element settings by:
estimating, using the output files output from the simulations, fault impedances associated with the respective events simulated; and
verifying the impedance-based element settings as a function of the estimated fault impedances.

28. The non-transitory computer-readable medium of claim 15, wherein the instructions, when executed by the processor, cause the processor to configure the protective relay with the relay settings as adapted.

29. Equipment for single-ended traveling wave-based protection of an electric power system, the equipment comprising:
processing circuitry configured to:
obtain relay settings for a protective relay specifying characteristics of traveling waves attributable to fault events that are to trip the protective relay;
perform simulations of events in the electric power system under different power system configurations, with the events including fault events and non-fault events, to obtain, for each of the simulations, an output file indicating characteristics of traveling waves attributed to the event simulated; and
iteratively adapt the relay settings for the protective relay over one or more iterations, wherein adapting the relay settings in each iteration comprises:
for each of the simulations, parsing the output file for the simulation to identify characteristics of traveling waves attributed to the event simulated, applying the relay settings to the identified characteristics to determine an observed local response of the protective relay to the simulated event, and generating comparison data that compares the observed local response of the protective relay to the simulated event with an expected local response of the protective relay to the simulated event; and
revising the relay settings for the protective relay based on the comparison data generated for the simulations.
